(19) United States
(12) Patent Application Publication
(10) Pub. No.: US 2023/0385479 A1
(43) Pub. Date: Nov. 30, 2023

(54) MAKING A MEASUREMENT RELATING TO AN OBJECT DEPENDING ON A DERIVED MEASUREMENT SURFACE

(71) Applicant: Hewlett-Packard Development Company, L.P., Spring, TX (US)

(72) Inventors: Faisal Azhar, Bristol (GB); Stephen POLLARD, Bristol (GB); Sven Molkenstruck, Braunschweig (DE); Guy ADAMS, Bristol (GB)

(21) Appl. No.: 18/031,573

(22) PCT Filed: Oct. 13, 2020
(86) PCT No.: PCT/US2020/055359

§ 371 Date: Apr. 12, 2023

(51) Int. Cl. G06F 30/20; G01B 21/20; B33Y 50/00; B33Y 50/02; B29C 64/386; B29C 64/393; B22F 10/31; B22F 10/85

(52) U.S. Cl. CPC G06F 30/20; G01B 21/20; B33Y 50/00; B33Y 50/02; B29C 64/386; B29C 64/393; B22F 10/31; B22F 10/85

(57) ABSTRACT

A method of making a measurement relating to an object manufactured according to a model may be provided. The object may have a measured surface comprising a surface deviation relative to a corresponding surface of the model. The method may comprise obtaining measured surface data representing at least a portion of the measured surface comprising the said surface deviation. The method may comprise determining a measurement surface corresponding to the measured surface of the object by performing a statistical analysis of at least a portion of the measured surface data in respect of an interpretation direction such that a portion of the measured surface data is offset from the measurement surface in the interpretation direction. The method may comprise making a measurement relating to the object depending on the measurement surface.

### BACKGROUND

A three-dimensional object may be produced using a manufacturing process, such as an additive manufacturing process which involves generating the object on a layer-by-layer basis. Such objects are often manufactured according to a three-dimensional model. Once manufactured, it is often useful to obtain measurements of the object. Such measurements may be assessed, for example against the three-dimensional model, to give an indication of accuracy of the object and/or the manufacturing process.

### BRIEF INTRODUCTION OF THE DRAWINGS

Example implementations are now described with reference to the accompanying drawings in which:

FIG. 1 is an example flow chart illustrating a method of making a measurement relating to an object;

FIG. 2 is an example block diagram of an apparatus having processing circuitry;

FIG. 3 is an example block diagram of a non-transitory machine-readable medium;

FIG. 4 is an example flow chart illustrating a method of identifying a surface of an object in data representing at least a portion of the object;

FIG. 5 is an example block diagram illustrating a model augmented with shape data;

FIG. 6 is an example flow chart illustrating a method of grouping points corresponding to model faces;

FIG. 7 is an example flow diagram illustrating a method of associating model data with scan data;

FIG. 8 is an example block diagram illustrating a system for manufacturing an object by additive manufacturing and subsequently measuring the object;

FIG. 9 illustrates an example three-dimensional scan of an example snowflake calibration object manufactured by additive manufacturing;

FIG. 10 illustrates example three-dimensional scan data representing an upper surface of the object of FIG. 9;

FIG. 11 shows an example plurality of parallel cross sections through the scan data of FIG. 10, the cross sections being spaced from each other in the y direction;

FIG. 12 is an example 2D superposition of data points representing the cross sections of FIG. 11 in the x-z plane;

FIGS. 13a, 13b show example joint surface fitting of surfaces to a pair of upper surfaces of the object of FIG. 9;

FIGS. 14a, 14b show example joint surface fitting of surfaces to opposite upper and lower surfaces of the object of FIG. 9;

FIG. 15 shows example data points of FIG. 12 with a measurement surface passing through a k^{th} percentile data point of the said data points in respect of an interpretation direction;

FIG. 16 shows example data points of FIG. 12 with a surface fit to the said data points;

FIG. 17 shows the example diagram of FIG. 16 with an example surface fit translated along an interpretation direction based on a statistical analysis of measured surface data in respect of an interpretation direction;

FIG. 18 shows an example non-planar interpretation surface being translated along an interpretation direction based on a statistical analysis of measured surface data in respect of the said interpretation direction; and

FIG. 19 shows an example in which an object is provided with a surface angled with respect to a layering direction in which the object is manufactured.

### DETAILED DESCRIPTION

Additive manufacturing techniques may generate a three-dimensional object through the solidification of a build material. In some examples, the build material may be a powder-like granular build material, which may for example be a plastic, ceramic or metal powder. Build material may be deposited, for example on a print bed and processed layer by layer, for example within a fabrication chamber. Other manufacturing techniques, including for example subtractive manufacturing, casting, injection moulding and machining, may also be used to generate three-dimensional objects. Additive manufacturing may be referred to as three-dimensional printing.

Manufacturing systems, such as additive manufacturing systems, may generate objects based on structural design data. This may involve a designer generating a model, such as a three-dimensional model, of an object to be generated, for example using a computer aided design (CAD) application. The model may be a computer model. The model may define the solid portions of the object. To generate a three-dimensional object from the model using an additive manufacturing system, the model data can be processed to generate slices of parallel planes of the model. Each slice may define a portion of a respective layer of build material that is to be solidified or caused to coalesce by the additive manufacturing system.

A three-dimensional object may be represented in terms of a set of vertices, edges and faces. Such a representation may be referred to as a polygon mesh, or a polygon mesh model. An example of a polygon mesh is a triangle mesh, where each of the faces are triangular in shape. Typically, the structural design data of a three-dimensional model, for example, from a CAD system, may be transformed into a polygon mesh model for processing in the actual manufacturing process. The polygon mesh model generated from a CAD model may further comprise other information about surface properties and appearance of the object. A polygon mesh model may be represented in a referential scheme as a list of vertices, faces and possibly edges, where each face comprises the indices of the included vertices (or edges which in turn reference the vertices). A polygon mesh model may be represented such that the vertex geometry could be explicit in each face. That is, each polygonal face could be represented as an N×3 matrix where each row of the matrix represents the X, Y and Z coordinates of the N vertices in the face (where N=3 for a triangular mesh). One limitation of this representation is that the mesh adjacencies are not made explicit as they are in the referential scheme where faces are deemed neighbours if they share a common vertex reference (in fact in such a scheme each vertex may have a link to a list of neighbouring faces). However, in certain referential polygon mesh models, the vertices are repeated for each polygonal face for which they are a part and hence the explicit relationships are lost. It is possible to alternatively represent a 3D model using voxels.

Once an object has been manufactured according to a three-dimensional model, it is often desirable to measure the manufactured object to assess the accuracy and quality of the manufactured object and the manufacturing process. For objects to be mass manufactured, it is possible to design bespoke measuring systems to take the desired measurements. However, for some manufacturing techniques such as additive manufacturing, the number of objects to be manufactured is often relatively small. Implementing bespoke metrology systems for such objects is often impractical, both in relation to time and cost. Furthermore, known methods of specifying the desired accuracy of a manufactured article may not take into account issues that may arise in the process of additive manufacturing.

Furthermore, in an additive manufacturing process, it may also be useful to deduce certain process control parameters of the manufacturing process. In some applications, this information may be more useful than specific measurements of the object. For additive manufacturing, it is useful to obtain the print process parameters such as scale and offset measurements of the object. Process control parameters may be derived from the print process parameters. The process control parameters may then be used of to correct the geometry of the printing process through updates to the additive manufacturing apparatus control or calibration parameters. An individualized pre-compensation of the model on which the object is based may additionally or alternatively be derived from the print process parameters.

An image or scan, such as a two-dimensional or three-dimensional scan, of the object may be used to virtually measure the manufactured object. Analysis of the image or scan of the object in comparison with the model can be used to provide information on the accuracy of the manufacturing process and the print process parameters.

However, it may be that the object does not accurately conform to the three-dimensional model from which it was created, for example due to a surface of the object having a surface deviation (e.g. relative to the corresponding surface of the model), such as a surface deformation, surface roughness or both a surface deformation and surface roughness, which may be caused by the additive manufacturing process. The surface of the manufactured object may thus comprise a surface deviation relative to the corresponding surface of the model on which it is based, such as a surface deformation. It may be that the surface deviation is a systematic surface deviation (e.g. a systematic surface deformation). It may be that the surface deviation comprises a non-linear surface deviation, such as a non-linear surface deformation. In an example, a surface of the manufactured (e.g. metallic) object may suffer from temperature-induced slumping. In another example, the manufactured object may have a surface, such as an upper surface, which comprises a sink (or meniscus) formed, for example, as a result of surface tension effects on the sides of the surface or due to sagging of a central portion of the surface which may be caused by the edges of the surface cooling from a molten form before the central portion. Measuring the surface based on a base portion of the sink can lead to under-estimations of object dimensions. Surface roughness can provide object surfaces with outlier portions which deviate significantly from the majority of the surface. Measuring the surface based on the outlier points can lead to over-estimations of object dimensions.

It is difficult to robustly measure dimensions of objects having surfaces comprising such a surface deviation using existing techniques, particularly when it is considered that the image or scan data on which measurements are based may also comprise noise which can further affect measurements. More robust measurement techniques may allow for improved quality control, more accurate calibration of additive manufacturing apparatus and more accurate pre-compensations to be applied to the model according to which future objects are manufactured.

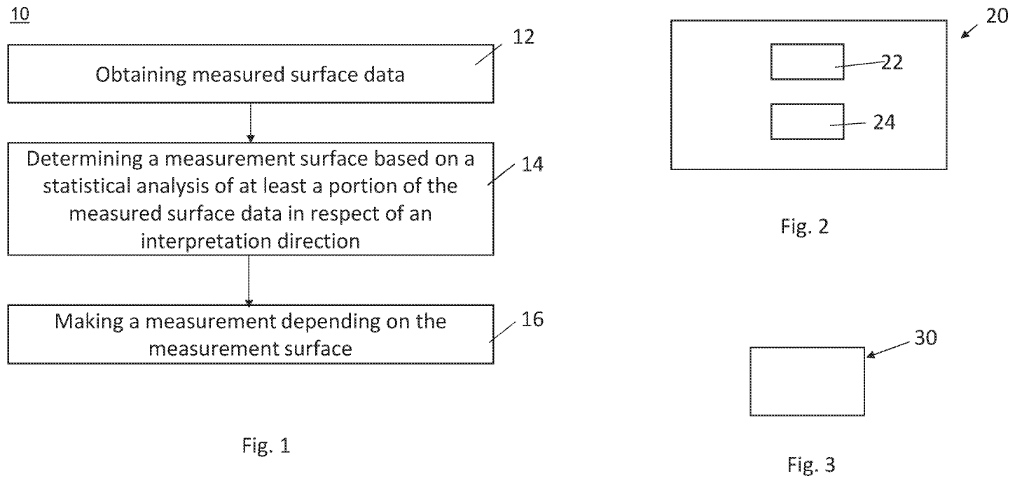

Referring now to FIG. 1, there is shown an example flow chart of a method, indicated generally by reference numeral 10, for making a measurement relating to an object, such as an object manufactured by way of an additive manufacturing technique.

It may be that the object is manufactured according to a model, such as a computer model, such as a CAD model. It may be that the model is a three-dimensional (3D) model. It may be that the object has a (e.g. external) measured surface (e.g. a surface on which a measurement is to be based) comprising a surface deviation relative to a corresponding surface of the model. The surface deviation may be caused by the (e.g. additive) manufacturing technique used to manufacture the object. The surface deviation may comprise surface roughness. The surface deviation may comprise a surface deformation, such as a non-linear surface deformation, such as a sink. The presence of the surface deviation (e.g. the surface deformation, such as a sink) in the measured surface may be known a priori or it may be detected from the data representing the measured surface (e.g. prior to performance of the method 10).

It may be that the method 10 is automated. The method 10 may be a computer-implemented method. For example, with reference to FIG. 2, the method 10 may be performed by an example apparatus 20 comprising processing circuitry 22. The apparatus 20 may further comprise a memory 24 in communication with the processing circuitry 22. The memory 24 may store machine-readable executable instructions executable by the processing circuitry 22 which, when executed by the processing circuitry 22, cause the processing circuitry 22 to perform the method of FIG. 1. As illustrated by FIG. 3, the executable instructions may be stored on an example non-transitory machine-readable storage medium 30. The processing circuitry 22 may be general purpose or special purpose processing circuitry for executing the machine-readable instructions stored in memory 24. In other implementations, the processing circuitry 22 may be to perform the method of FIG. 1 based on a hardware implementation such as a field programmable gate array (FPGA) or in any combination of hardware, software (e.g. comprising machine-readable instructions), firmware.

The method 10 may comprise, at 12, obtaining (e.g. the processing circuitry 22 receiving as an input) measured surface data representing at least a portion of the measured surface comprising the said surface deviation. The measured surface data may comprise a plurality of data points representing the measured surface. The measured surface data may comprise image or scan data representing the at least a portion of the measured surface. For example, the measured surface data may comprise two dimensional, 2D, or three-dimensional, 3D, image or scan data providing a 2D or 3D representation of the at least a portion of the measured surface. The measured surface data may comprise 2D optical comparator data providing a 2D representation of the at least a portion of the measured surface (which may for example be based on data from an optical comparator) or 3D structured light scanner data providing a 3D representation of the at least a portion of the measured surface (which may for example be based on data from a 3D structured light scanner, such as a GOM 3D structured light scanner). The measured surface data may be generated by any suitable alternative imaging or scanning technique. The image or scan data may be obtained by imaging or scanning at least a portion of the object by way of an imager or scanner, for example after the object has cooled after additive manufacture thereof.

It may be that the measured surface data representing at least a portion of the measured surface is obtained based on data representing at least a portion of the object, such as at least a portion of the object comprising the measured surface. It may be that the data representing the at least a portion of the object comprises surface data representing a further surface of the object or surface data representing a plurality of further surfaces of the object other than the measured surface. The further surface or further surfaces of the object may be external surfaces of the object.

The method may comprise, at 14, (e.g. the processing circuitry 22) determining a (e.g. virtual) measurement surface corresponding to the measured surface of the object based on a statistical analysis of at least a portion of the measured surface data (e.g. selectively) in respect of an (e.g. virtual) interpretation direction (e.g. selectively in the interpretation direction as opposed to in both the interpretation direction and in a direction opposite the interpretation direction). The method may comprise determining a statistical metric based on a statistical analysis of at least a portion of the measured surface data (e.g. selectively) in respect of an interpretation direction (e.g. selectively in the interpretation direction as opposed to in both the interpretation direction and in a direction opposite the interpretation direction). The method may comprise determining the measurement surface depending on the statistical analysis or metric. The at least a portion of the measured surface data may comprise the surface deviation (e.g. surface deformation). The at least a portion of the measured surface data may comprise at least a portion of the surface deviation (e.g. at least a portion of the surface deformation) such as at least a prominent portion of the surface deviation (e.g. at least a prominent portion of the surface deformation).

For example, the statistical analysis, the statistical metric or the statistical analysis and the statistical metric may be based on offsets of data points of at least a portion of the measured surface data in the interpretation direction. For example, the offsets may be offsets with respect to a (e.g. predefined) plane or data point. The offsets may be offsets with respect to an imager or scanner reference plane. The imager or scanner reference plane may be a reference plane with respect to which values of the data points are defined (e.g. by the scanner) in the interpretation direction. For example, the offsets may be values of 2D or 3D data points of the measured surface data in a predefined dimension (e.g. z-direction) of the measured surface data. The dimensions of the measured surface data may depend on a co-ordinate system of the imager or scanner.

The interpretation direction may comprise a predefined direction (e.g. a vertically upwards or vertically downwards direction). The interpretation direction may be predefined by way of the measured surface data. For example, the interpretation direction may be based on a (e.g. 2D or 3D) co-ordinate system on which the measured surface data is based. For example, the interpretation direction may be based on a predefined dimension of the measured surface data. For example, the interpretation direction may comprise a vertically upwards or vertically downwards direction (e.g. a z-direction) based on a co-ordinate system on which the measured surface data is based. In this case, the image or scan data may be determined with the object aligned with the imager or scanner with reference to the intended interpretation direction. For example, the object may be selectively aligned with axes of the imager or scanner for the imaging or scanning.

Additionally or alternatively, the interpretation direction may be derived from reference surface data (e.g. image or scan data) representing a reference surface of the object or a plurality of reference surfaces of the object. For example, the interpretation direction may be determined based on a (e.g. virtual) surface or (e.g. virtual) surfaces based on (e.g. fit to) reference surface data representing the reference surface or reference surfaces of the object.

The method may comprise obtaining the reference surface data representing the reference surface or reference surfaces of the object. The reference surface or reference surfaces of the object may comprise the measured surface. The reference surface or reference surfaces of the object may comprise a further surface or a plurality of further surfaces of the object other than the measured surface. The reference surface or surfaces may comprise a plurality of reference surfaces comprising the measured surface and a further surface or further surfaces of the object other than the measured surface. The further surface or further surfaces may be any surface or surfaces of the object other than the measured surface. The further surface or further surfaces may correspond to (e.g. planar) model surfaces which are parallel to the (e.g. planar) model surface corresponding to the measured surface. The further surface or further surfaces may correspond to model surfaces which are not parallel to the model surface corresponding to the measured surface. Determining the interpretation direction from reference surface data allows the interpretation direction to be determined even when the measured surface data is not aligned with reference to the interpretation direction during scanning.

The interpretation direction may be based on surfaces jointly fit to data representing at least respective portions of a plurality of reference surfaces. The surfaces fit to the reference surface data representing at least respective portions of the said plurality of reference surfaces may be provided with a common or parallel normals. A normal of a surface may be considered to be a (e.g. notional or virtual) line extending (e.g. outwards) from the surface perpendicularly to the surface. A normal may have a direction, such as a direction extending (e.g. outwards) perpendicularly away from the said surface. Reference surface data relating to each of the reference surfaces may be combined for a multi-plane fit (e.g. a multi-plane fit with common or parallel normals). A multi-plane fit may allow for a more accurate determination of the interpretation direction. The reference surfaces may be categorised according to any of co-planarity, common surface normal, common (e.g. surfaces having co-linear or parallel normals in the same direction) or opposite (e.g. surfaces having co-linear or parallel normals but in opposite directions) polarity, for example based on corresponding surfaces of the model on which the object is based. Reference surface data representing reference surfaces categorised in the same category may be combined in respective multi-plane fits. Where a multi-plane fit is performed based on reference surface data representing a plurality of reference surfaces of the object, it may be that the surfaces of the model corresponding to the reference surfaces are substantially parallel to each other. It may be that the surfaces of the model corresponding to the said reference surfaces of the object which are combined for a multi-plane fit are planar surfaces.

The interpretation direction may be parallel to or co-linear with a normal of a surface or a common or parallel normal of surfaces based on (e.g. fit to) the reference surface data. In other examples, the interpretation direction may be at an (e.g. non-zero) angle to (e.g. non-parallel to) a normal of the surface or to a common or parallel normal of (e.g. a plurality of) the surfaces based on (e.g. fit to) the reference surface data.

For example, the reference surface or surfaces may comprise the measured surface. It may be that the interpretation direction is based on a normal to a surface fit to the measured surface. For example, determining the interpretation direction may comprise determining the interpretation direction to be in a direction of a normal to the surface fit to the measured surface. The method may comprise performing a surface fit to the reference surface data representing the measured surface. The surface fit to the measured surface may be based on a multi-plane fit to reference surface data representing the measured surface and a further surface or further surfaces of the object, which further surface or further surfaces may correspond to surfaces of the model which are parallel with or have common or parallel normals to the model surface corresponding to the measured surface. The method may comprise performing a multi-plane fit to the reference surface data representing the measured surface and a further surface or further surfaces of the object, the measured surface and further surface or further surfaces being provided with common or parallel normals. The interpretation direction may be based on (e.g. co-linear with or parallel to) a common or parallel normal provided to the surfaces fit to the measured surface and the further surface or further surfaces for the said multi-plane fit. As set out above, a multi-plane fit may allow for a more accurate determination of the interpretation direction.

The reference surface or surfaces may comprise a further surface or further surfaces of the object corresponding to (e.g. planar) surfaces of the model which are parallel with or have common or parallel normals to the (e.g. planar) model surface corresponding to the measured surface. It may be that determining the interpretation direction comprises determining the interpretation direction to be co-linear or parallel to (e.g. in a direction of) a normal to a surface fit to reference surface data representing a said further surface of the object other than the measured surface. The method may comprise performing a surface fit to the reference surface data representing the further surface. The reference surface or surfaces may comprise a plurality of such further surfaces. The method may comprise performing a multi-plane fit to the reference surface data representing the said further surfaces of the object, the surfaces fit to the said further surfaces being provided with common or parallel normals. The interpretation direction may be based on (e.g. co-linear with or parallel to) the common or parallel normals provided to surfaces fit to the further surfaces for the said multi-plane fit.

It may be that the reference surface or surfaces of the object comprise a plurality of reference surfaces. It may be that the plurality of reference surfaces comprises a plurality of further surfaces of the object other than the measured surface. It may be that, for at least one reference surface of the plurality of reference surfaces, a surface of the model corresponding to the at least one reference surface is oriented differently (e.g. has a non-parallel normal) from the model surface corresponding to the measured surface. It may be that the model surfaces corresponding to at least two of the plurality of reference surfaces are oriented differently from each other. Determining the interpretation direction may comprise determining the interpretation direction depending on surfaces fit to the reference data representing the said plurality of reference surfaces. Determining the interpretation direction may comprise determining the interpretation direction depending on normals to surfaces fit to the reference data representing the said plurality of reference surfaces. The interpretation direction may be at an (e.g. non-zero) angle to the said normals. It may be that the interpretation direction is non-parallel to the said normals. It may be that the interpretation direction is non-parallel to a normal to the model surface corresponding to the measured surface. The interpretation direction may be determined based on a predetermined (e.g. based on the model on which the object is based) relationship between the (e.g. normals to the) reference surfaces and the interpretation direction. The interpretation direction may be determined based on the said normals to the said reference surfaces.

Determining the interpretation direction may depend on prior knowledge of an orientation in which the object was manufactured (e.g. the layering or z direction of the 3D printing process for manufacturing the object relative to the model).

It may be that the interpretation direction is parallel to a layering direction of an additive manufacturing process by which the object is manufactured (e.g. a direction in which layers are stacked one on top of the other during additive manufacture). It may be that the interpretation direction corresponds to a vertical (e.g. a vertically upwards) direction. In some examples in which the surface deviation comprises a sink, it may be that the interpretation direction is parallel or substantially parallel to a sink direction (e.g. a direction of concavity) of the measured surface. Alternatively, in some examples, it may be that the interpretation direction is angled (e.g. non-parallel) to the sink direction.

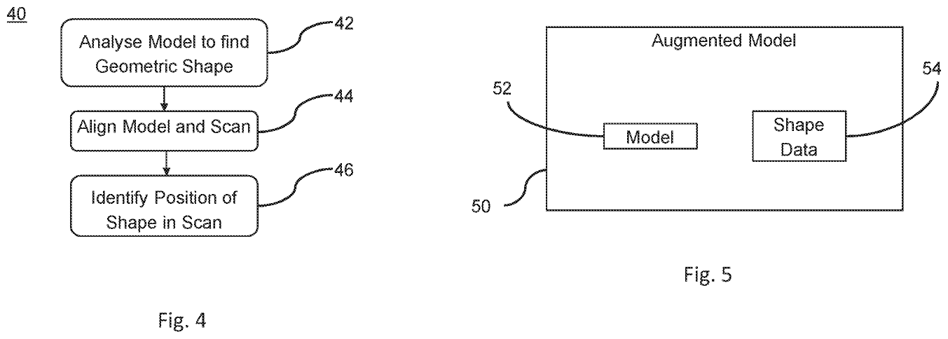

In some examples, determining the interpretation direction may comprise aligning (e.g image or scan) data representing at least a portion of the object with the model on which the object is based and determining the interpretation direction based thereon (e.g. the interpretation direction may be a layering direction in respect of which the object was manufactured according to the model, the layering direction with respect to the model being known). As explained below with reference to FIG. 4, it may be that the said aligning the data representing the said at least a portion of the object with the model comprises aligning surfaces of the model with corresponding surfaces of the data representing the object.

It may be that the measurement surface is determined by performing the said statistical analysis such that a portion of the measured surface data is offset from (beyond) the measurement surface in the interpretation direction. It may be that the portion of the measured surface data offset from (beyond) the measurement surface in the interpretation direction comprises noise of the measured surface data, outlier data representing outlier portions of the measured surface data or both noise and outlier data. It may be that the portion of the measured surface data offset from (beyond) the measurement surface in the interpretation direction is a predetermined proportion of the measured surface data. It may be that the portion of the measured surface data offset from (beyond) the measurement surface in the interpretation direction is a portion of the measured surface data in accordance with a predetermined metric (e.g. a (1−k)th percentile of the measured surface data, where k is a predefined value). It may be that the measurement surface corresponds to an estimated extremity or edge of the measured surface in respect of the interpretation direction, including the said surface deviation thereof.

The method may comprise, at 16, (e.g. the processing circuitry) making a (e.g. virtual) measurement, such as a measurement relating to the object, depending on the (e.g. virtual) measurement surface. For example, the measurement may comprise a distance or displacement measurement between the measurement surface and a further (e.g. virtual) surface of the object or between the measurement surface and some other reference surface or plane. Where provided, a (e.g. virtual) surface corresponding to a reference surface of the object other than the measured surface may be derived from reference surface data (e.g. image or scan data as discussed above) representing at least a portion of the reference surface, such as by fitting a (e.g. virtual) surface to reference surface data representing the reference surface of the object. It may be that the measured surface data and the reference surface data are provided by image or scan data representing at least a portion of the object comprising at least a portion of the measured surface and at least a portion of the reference surface other than the measured surface.

By determining a measurement surface based on a statistical analysis of measured surface data in respect of an interpretation direction, and making a measurement based on the measurement surface, a robust measurement (e.g. relating to the object) can be performed which takes into account surface deviations of the object surface, such as surface deformations (e.g. a surface sink) or outlier points caused by surface roughness, and measurement noise. In particular, by the statistical analysis being performed, or statistical metric being obtained, in respect of the interpretation direction, the measurement surface is determined with a reduced influence from (e.g. scan) noise and outlier portions of the object. It may be that the measurement surface is based on an extent of the object or measured surface in the interpretation direction with a reduced influence from (e.g. scan) noise and outlier points by way of the statistical analysis or metric.

By obtaining a more robust measurement based on the measurement surface, the accuracy of the manufacturing technique, or a quality metric relating to the object, can be determined more robustly. Additionally or alternatively, print process parameters, such as scale and offset measurements of the object, and process control parameters or individualised pre-compensations to be applied to the model derived therefrom, can be obtained more robustly. As mentioned above, the process control parameters may then be used of to correct the geometry of the printing process through updates to the additive manufacturing apparatus control and calibration parameters. Individualized pre-compensation can additionally or alternatively be applied to the model on which the object is based, thereby allowing the quality or accuracy of the (e.g. additive) manufacturing technique to be improved.

The method of FIG. 1 is not restricted to objects manufactured by additive manufacturing and is equally applicable to objects manufactured by other manufacturing techniques such as injection moulding or subtractive manufacturing.

It may be that the measurement surface is a surface of predefined shape. For example, it may be that the measurement surface is a measurement surface of a shape predefined by the model in accordance with which the object is manufactured. The predefined shape may be planar. The predefined shape may be non-planar. The predefined shape may comprise a 2D geometric shape (e.g. corresponding to a plan view of the surface). The predefined shape may comprise a curved portion. The predefined shape may comprise a shape of a cross section through the measurement surface in the interpretation direction. The predefined shape may comprise both a 2D geometric shape (e.g. corresponding to a plan view of the surface) and a shape of a cross section through the measurement surface in the interpretation direction. The predefined shape may comprise a predefined 3D shape of the said surface. The predefined shape may comprise a freeform 3D shape of the said surface.

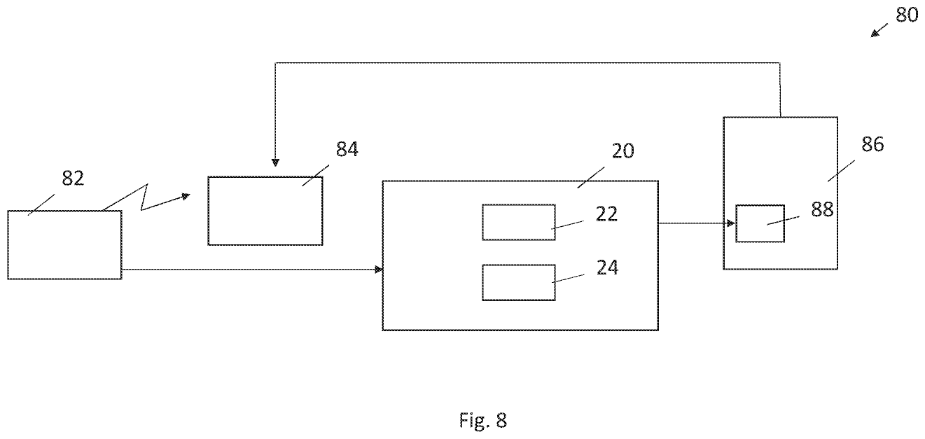

FIG. 8 is a schematic diagram of an example system 80. The system 80 may comprise an imager or scanner 82 for imaging or scanning an object 84. The object may have been manufactured in an additive manufacturing apparatus (such as a 3D printer) 86. The object 84 may be cooled before imaging or scanning by the scanner 82. Data representing at least a portion of the object 84 (such as image or scan data representing at least a portion of the object 84) may be communicated from the imager or scanner 82 to apparatus 20 comprising the processing circuitry 22. As discussed above, the apparatus 20 may further comprise a memory 24 in communication with the processing circuitry 22. The processing circuitry 22 of the apparatus 20 may be to perform the method 10 discussed above in order to make a measurement relating to the object 84. Data relating to the measurement may be communicated from the apparatus 20 to a controller 88 of the additive manufacturing apparatus 86, for example in order for the controller 88 of the additive manufacturing apparatus 86 to update a control or calibration parameter (e.g. scale, offset or scale and offset parameters) of the apparatus, a pre-compensation (e.g. scale, offset or scale and offset pre-compensations) applied to a model according to which the object 84 was manufactured, or both a control or calibration parameter and a pre-compensation applied to the model. The additive manufacturing apparatus may then be caused to manufacture future objects according to the model in accordance with the updated control or calibration parameter, pre-compensation or control or calibration parameter and pre-compensation.

Although the apparatus 20 is illustrated as being separate from the additive manufacturing apparatus 86, it may be that the apparatus 20 is alternatively integrated with the additive manufacturing apparatus 86. For example, the processing circuitry 22 of the apparatus may be integrated with the controller 88 of the additive manufacturing apparatus 86.

Determining the (virtual) measurement surface by the said statistical analysis of the at least a portion of the measured surface data may comprise identifying a data point corresponding to a k^{th} percentile data point of the at least a portion of the measured surface data ordered in respect of the interpretation direction. The method may comprise determining the measurement surface depending on the identified data point. In an example, it may be that the measurement surface is to pass through the identified data point. The statistical metric may thus comprise a k^{th} percentile data point of the at least a portion of the measured surface data ordered in the interpretation direction. The k^{th} percentile data point is an efficiently determined statistical metric which allows an effective and robust measurement plane to be determined with limited processing overhead.

The statistical analysis may comprise a statistical analysis of offsets in the interpretation direction of a selected portion of the measured surface data. The selected portion of the measured surface data may be a selected portion of the measured surface data which is offset beyond the said k^{th} percentile data point in the interpretation direction (e.g. and not including the portion of the measured surface data which is offset beyond the said k^{th} percentile point in the opposite direction to the interpretation direction).

For example, the statistical analysis may comprise determining an average (e.g. mean or median) offset of the selected portion of the measured surface data beyond the k^{th} percentile data point in the interpretation direction. The method may comprise determining the measurement surface based on the average offset of the selected portion of the measured surface data beyond the k^{th} percentile data point in the interpretation direction. For example, it may be that the measurement surface is to pass through a data point corresponding to the average offset of the selected portion of the measured surface data beyond the k^{th} percentile data point in the interpretation direction. The statistical metric may thus comprise an average (e.g. mean or median) offset of the selected portion of the measured surface data beyond the kth percentile data point in the interpretation direction.

In another example, the method may comprise determining the measurement surface by fitting a surface (such as a surface of predefined shape, for example based on a or the shape of the surface of the model corresponding to the measured surface of the object) to a selected portion of the measured surface data. The selected portion of the measured surface data may be a selected portion of the measured surface data which is offset beyond the said k^{th} percentile data point in the interpretation direction (e.g. and not including the portion of the measured surface data which is offset beyond the said k^{th} percentile point in the opposite direction to the interpretation direction). Any suitable surface fitting technique may be employed, such as a least-squares fitting technique (e.g. for minimising a least squares error function between the said surface and the selected portion of the measured surface data). It may be that the surface fitting is based on an iterative weighted least squares function such as an iterative weighted least squares version of M-Estimation with a Turkey weighting function to eliminate outlier points of the selected portion of the measured surface data. It may be that the weights are determined by the size of the residual at the previous iteration (or fit). It may be that the residuals are in a dimension (e.g. z-dimension) parallel to the interpretation direction.

It may be that k is a predefined percentile value. The value of k may be selected depending on the nature of the statistical analysis to be performed. It may be that k is a value between 80 and 99.9, between 90 and 99.9, between 93 and 99, or between 94 and 98. For example, it may be that k is equal to 97.5. Thus, it may be that a portion (e.g. between 0.1 and 20%, between 0.1 and 10%, between 1 and 7%, between 2 and 6% or 2.5%) of the measured surface data (which may be a predefined proportion of the measured surface data, or a predefined proportion of at least a portion of the measured surface data) is offset beyond the measurement surface in the interpretation direction. As mentioned above, it may be that the portion of the measured surface data offset beyond the measurement surface in the interpretation direction (e.g. selectively) comprises noise of the measured surface data, outlier data representing outlier portions of the measured surface or both noise and outlier data. For example, k may be selected such that the portion of the measured surface data offset beyond the measurement surface in the interpretation direction comprises noise of the measured surface data, outlier data representing outlier portions of the measured surface or both noise and outlier data.

It may be that the measurement surface is a planar surface. It may be that the measurement surface is a non-planar surface. It may be that the model surface corresponding to the measured surface is a planar surface. It may be that the model surface corresponding to the measured surface is a non-planar surface.

In some examples, it may be that determining the measurement surface at 14 comprises: providing an interpretation surface (such as a surface of predefined shape, for example based on a or the shape of the surface of the model corresponding to the measured surface of the object); and positioning the interpretation surface at a position along the interpretation direction which depends on the said statistical analysis or metric.

In some examples, it may be that determining the measurement surface at 14 comprises: orienting, or aligning and orienting, an interpretation surface (such as a surface of predefined shape, for example based on a or the shape of the surface of the model corresponding to the measured surface of the object) with respect to the at least a portion of the measured surface data; and providing the oriented, or aligned and oriented, interpretation surface at a position along the interpretation direction which depends on the said statistical analysis or metric.

Aligning the interpretation surface with respect to the measured surface data may comprise aligning the interpretation surface such that notional straight lines parallel to the interpretation direction passing through data points of the at least a portion of the measured surface data pass through the interpretation surface.

It may be that the interpretation surface is oriented based on the interpretation direction. For example, the interpretation surface may be perpendicular to the interpretation direction. By basing the orientation of the interpretation surface on the interpretation direction, the interpretation surface can be efficiently determined.

As mentioned above, it may be that the statistical analysis comprises identifying the said data point corresponding to the k^{th} percentile data point of the at least a portion of the measured surface data ordered in respect of the interpretation direction. The method may comprise positioning the interpretation surface with respect to the interpretation direction depending on the identified data point (e.g. such that the interpretation surface passes through the identified data point). The measurement surface may comprise the said positioned interpretation surface.

It may be that the statistical analysis or metric depends on an analysis of offsets of at least a selected portion of the measured surface data from the (e.g. oriented or aligned and oriented) interpretation surface in the interpretation direction, the at least a selected portion of the measured surface data being offset in the interpretation direction beyond the interpretation surface. It may be that the offsets of the at least a selected portion of the measured surface data are measured relative to an (e.g. oriented or aligned and oriented) interpretation surface of predefined shape. For example, determining the measurement surface may comprise identifying a data point corresponding to the k th percentile data point of the offsets in the interpretation direction of the at least a selected portion of the measured surface data relative to the interpretation surface (e.g. of predefined shape, e.g. based on the model surface corresponding to the measured surface of the object). The method may comprise positioning the interpretation surface depending on the identified data point (e.g. such that the interpretation surface passes through the identified data point).

For example, the measurement surface may comprise the said positioned interpretation surface. In another example, the statistical analysis may comprise determining an average (e.g. mean or median) offset of a selected portion of the measured surface data beyond the interpretation surface in the interpretation direction, for example relative to the predefined shape of the interpretation surface. The selected portion of the measured surface data may be offset in the interpretation direction beyond the interpretation surface. The method may comprise determining the measurement surface based on the average offset. For example, it may be that the measurement surface is positioned or translated in the interpretation direction depending on the average offset.

In another example, the method may comprise fitting the measurement surface (such as a surface of predefined shape, for example based on a or the shape of the surface of the model corresponding to the measured surface of the object) to a selected portion of the measured surface data. The selected portion of the measured surface data may be offset in the interpretation direction beyond the interpretation surface. Any suitable surface fitting technique may be employed, such as a least-squares fitting technique (e.g. for minimising a least squares error function between the measurement surface and the selected portion of the measured surface data). It may be that the surface fitting is based on an iterative weighted least squares function such as an iterative weighted least squares version of M-Estimation with a Turkey weighting function to eliminate outlier points of the said selected portion of the measured surface data. It may be that the weights are determined by the size of the residual at the previous iteration (or fit). It may be that the residuals are in a dimension (e.g. z-dimension) parallel to the interpretation direction.

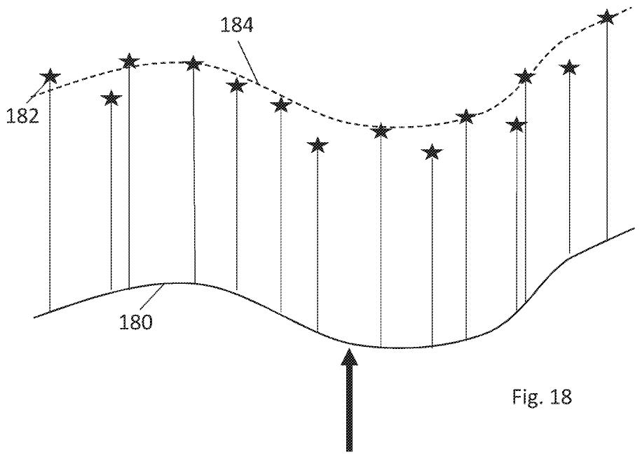

It may be that the interpretation surface is a planar surface. It may be that the interpretation surface is a non-planar surface. In the case where the interpretation surface is a planar surface, although it may be that the interpretation surface is aligned with respect to the measured surface data, it may be that the interpretation surface is not aligned with respect to the measured surface data. Because the measurement surface is planar, virtual measurements may still be validly made between the measurement surface and data representing other surfaces of the object in the interpretation direction, for example, based on a plane co-planar with the planar measurement surface. In the case where the interpretation surface is a non-planar (e.g. curved) surface, it may be that the interpretation surface is both aligned and oriented with respect to the measured surface data. This alignment helps to enable the offsets of the at least a portion of the measured surface to be determined relative to the predefined shape of the interpretation surface (for example, see below in reference to FIG. 18).

It may be that the interpretation surface is (e.g. oriented or aligned and oriented) based on reference surface data (e.g. image or scan data) representing at least a portion of a reference surface of the object. It may be that providing the interpretation surface comprises (e.g. automatically) fitting an (virtual) interpretation surface (e.g. an interpretation surface having the predefined shape of the model surface corresponding to the measured surface) to reference surface data representing at least a portion of a reference surface of the object.

The reference surface of the object may comprise any of: the measured surface; a further surface of the object other than the measured surface.

Where the reference surface comprises the measured surface, it may be that the method comprises (e.g. automatically) fitting an (virtual) interpretation surface (e.g. a surface of predefined shape based on the model surface corresponding to the measured surface) to the measured surface data. The surface deviations of the measured surface relative to the corresponding surface of the model may cause some inaccuracy in the interpretation surface fit to the measured surface. Accordingly, the method may additionally or alternatively comprise determining (e.g. orienting or aligning and orienting) the interpretation surface by fitting a surface to reference surface data representing at least a portion of a further surface of the object other than the measured surface.

The surface fit or surface fits to the reference surface data may be performed using any suitable surface fitting technique, such as a least-squares fitting technique (e.g. for minimising a least squares error function between the interpretation surface and the reference surface data). It may be that the interpretation surface is fit to the reference surface data based on an iterative weighted least squares function such as an iterative weighted least squares version of M-Estimation with a Turkey weighting function to eliminate outlier points of the said reference surface data. It may be that the weights are determined by the size of the residual at the previous iteration (or fit). It may be that the residuals are in a dimension (e.g. z-dimension) parallel to the interpretation direction.

In some examples, particularly when the model surface corresponding to the measured surface is a planar surface, it may be that the method comprises determining the interpretation surface by (e.g. automatically) fitting respective surfaces (e.g. surfaces having the predefined shape of the model surface corresponding to the measured surface) to reference surface data representing at least respective portions of a plurality of reference surfaces of the object. The interpretation surface may be determined based on surfaces jointly fit to reference surface data representing a plurality of the said reference surfaces. The surfaces fit to the reference surface data may be provided with common or parallel normals. Reference surface data relating to each of the reference surfaces may be combined for a multi-plane fit. A multi-plane fit may allow for a more accurate determination of the interpretation surface, at least because the orientation of the surface fits may be determined more accurately. The surfaces of the object may be categorised according to any of co-planarity, common surface normal, common or opposite polarity, for example based on corresponding surfaces in the model on which the object is based. Reference surface data representing reference surfaces in the same category may be combined in respective multi-plane fits. Where a multi-plane fit is performed based on reference surface data representing a plurality of reference surfaces of the object, it may be that the surfaces of the model corresponding to the reference surfaces are substantially parallel to each other. The method may comprise selecting one of the respective jointly fit surfaces, such as one of the surfaces aligned with the measured surface data, as the interpretation surface.

The reference surfaces may comprise the measured surface and a further surface of the object other than the measured surface or the measured surface and a plurality of further surfaces of the object other than the measured surface. The reference surfaces may comprise a plurality of further surfaces of the object other than the measured surface.

The further surface or surfaces (where provided) may be any surface of the object other than the measured surface. In some examples, where the reference surface or surfaces comprise a further surface of the object other than the measured surface, it may be that the further surface of the object is aligned with the measured surface in the interpretation direction. For example, notional straight lines parallel to the interpretation direction passing through data representing the further surface in the interpretation direction may pass through the measured surface. In some examples, it may be that the further surface is based on a surface of the model having a common orientation (e.g. with respect to the interpretation direction) with the model surface corresponding to the measured surface. For example, it may be that the further surface is based on a surface of the model which is parallel to the model surface corresponding to the measured surface. Thus, it may be that a surface fit to the reference surface data representing the further surface is aligned, oriented or aligned and oriented with the measured surface data. It may be that the surface fit to the reference surface data representing the further surface is provided as the interpretation surface.

In some examples, it may be that the reference surface or surfaces comprise a further surface of the object which is not aligned with the measured surface in the interpretation direction. It may be that the reference surface or surfaces comprise a further surface which has a different orientation from the measured surface (or both a different orientation from the measured surface and it may be that it is not aligned with the measured surface). For example, it may be that the model surface corresponding to the further surface is at an angle (e.g. not parallel) to the model surface corresponding to the measured surface. If the further surface is not aligned with or if the further surface does not have the same orientation as the measured surface, it may be that a (e.g. precomputed) transformation, such as a rigid transformation [R t], is applied to surface derived from (e.g. fit to) reference surface data representing the said further surface in order to orient, align or orient and align the surface with respect to the measured surface (e.g. to provide the surface with the same orientation as the measured surface, to align the surface with the measured surface or both). It may be that the transformation comprises a rotation. It may be that the transformation comprises a translation. It may be that the transformation comprises a rotation and a translation. It may be that the said (e.g. aligned, oriented, or aligned and oriented) surface is provided as the interpretation surface. The transformation may be based on a predetermined (e.g. from the mode) relationship between the reference surface and the measured surface.

Whether the reference surface or surfaces comprise the measured surface, a further surface or further surfaces of the object other than the measured surface or both the measured surface and a further surface or further surfaces of the object other than the measured surface, it may be that the orientation, alignment or orientation and alignment of the measurement surface are determined based on the interpretation surface. For example, the orientation of the measurement surface may be the orientation of the interpretation surface. The measurement surface may be aligned with the interpretation surface. The (e.g. oriented or oriented and aligned) interpretation surface may be positioned along the interpretation direction based on the said statistical analysis to provide the measurement surface. As discussed above, this may involve translating or positioning the interpretation surface along the interpretation direction such that the interpretation surface passes through the k^{th} percentile point of the at least a portion of the measured surface data ordered in respect of the interpretation direction.

It may be that a further surface of the object other than the measured surface is preselected to be a reference surface based on the said further surface more closely matching or conforming to (or deviating less from), or being expected to more closely match or conform to (or deviate less from), its corresponding model surface than the measured surface. The said further surface may comprise a surface opposite the measured surface. For example, when the object is manufactured by an additive manufacturing technique, it may be that the measured surface corresponds to a higher or upper (e.g. top) layer while the one of the said further surfaces may correspond to lower or bottom or base layer. A lower or bottom or base layer may be more likely to better conform to its model surface, for example because lower or bottom or base layers are less likely to form sinks during cooling. In this way, a more accurate interpretation direction may be obtained based on the reference surface data representing the further surface than on fitting the interpretation surface to the said measured surface data (or on fitting the interpretation surface to the said measured surface data alone as the case may be). Similarly, more accurate alignment, orientation or alignment and orientation of the measurement surface with respect to the measured surface data may be obtained by fitting the interpretation surface to the reference surface data representing the said further surface than on fitting the interpretation surface to the said measured surface data (or on fitting the interpretation surface to the said measured surface data alone as the case may be).

It may be that determining the measurement surface based on the said statistical analysis comprises determining the measurement surface based on a statistical analysis of a restricted portion of the measured surface data corresponding to a predefined portion of the measured surface. The restricted portion of the measured surface data may correspond to a predefined portion or a predefined vicinity of the measured surface (e.g. where the surface deviation (e.g. surface deformation) is more prominent). For example, where the surface deviations of the measured surface are known to be more prominent around the edge of the measured surface, it may be that the statistical analysis comprises a statistical analysis of a restricted portion of the measured surface data corresponding to the edge of the measured surface. For example, when the measured surface is known to comprise a sink comprising a rim portion, a base portion and a curved surface extending between the rim portion and the base portion, it may be that the statistical analysis comprises a statistical analysis of a restricted portion of the measured surface data corresponding to the rim portion. The restricted portion of the measured surface data for including in the statistical analysis may be selected by way of a threshold distance from an expected location of (e.g. a prominent part of) the surface deviation (e.g. surface deformation), such as the rim or edge. Restricting the measured surface data for including in the statistical analysis may reduce processing overheads for determining the measurement surface. Restricting the measured surface data for including in the statistical analysis may also increase the robustness of the measurement as non-relevant data is ignored.

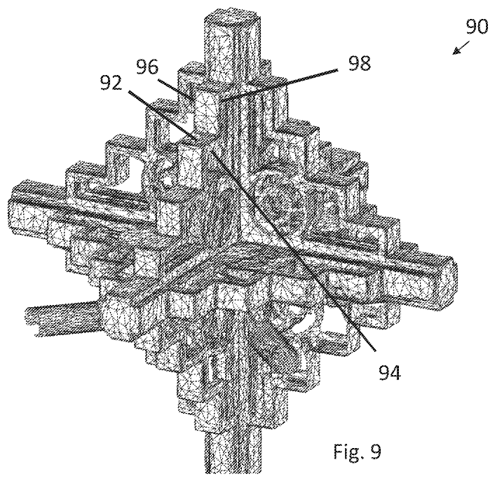

A 3D scan of an example “snowflake” object 90 manufactured by additive manufacturing, such as by the additive manufacturing apparatus 86, in accordance with a model is illustrated in the example of FIG. 9. The example object 90 may be a calibration object. The example object 90 has a plurality of upper surfaces 92, a plurality of lower surfaces 94 opposite the upper surfaces 92 and a plurality of opposite lateral surfaces 96, 98. Measurements can be made virtually between respective pairs of surfaces by way of (e.g. image or scan) data representing the object 90 in order to assess the quality of the object and the accuracy of the additive manufacturing process. Additionally or alternatively, such measurements may be used to update control or calibration parameters of the additive manufacturing apparatus (e.g. scale, offset or scale and offset) or to update pre-compensations applied to the model for manufacture of future objects according to the model.

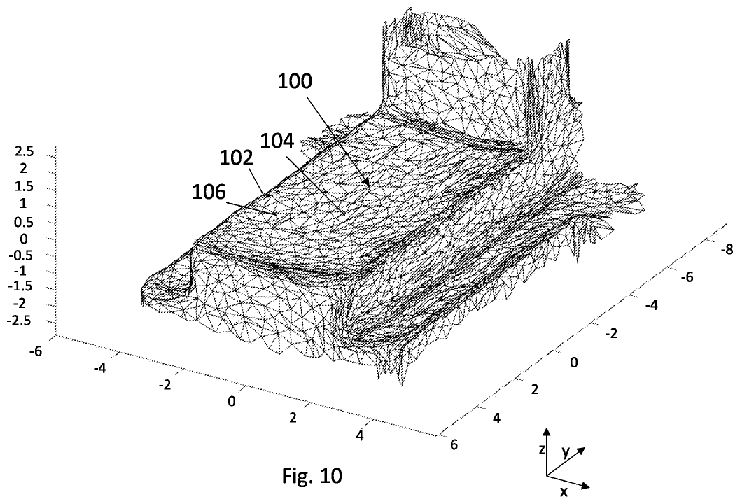

FIG. 10 shows example 3D scan data from a 3D scanner representing an upper surface 92 of a stepped portion of the object 90. The upper surface 92 may be considered to be a measured surface of the object 90, and the data representing the measured surface may be considered measured surface data, for example because a measurement relating to the object is to depend on a measurement surface corresponding to the measured surface. The surface of the model corresponding to the upper surface 92 of the object may be a planar surface.

The 3D scan data may be defined with respect to an x, y, z co-ordinate system indicated on FIG. 10. The 3D scan data (and thus the co-ordinates of the scan data) in this example is aligned with the co-ordinates of the additive manufacturing apparatus used to manufacture the object 90. The upper surface 92 may have a sink 100 comprising a rim portion 102 around the edge of the sink 100, a base portion 104 at a base of the sink 100 offset from the rim portion 102 in the negative z direction, and a curved surface 106 extending between the rim portion 102 and the base portion 104. The curved surface 106 and the base portion 104 generally form a concavity between respective portions of the rim 102. As discussed above, the sink may be formed during cooling of the object 90 due to sagging of a central portion of the surface 92 which may be caused by the edges (corresponding to the rim portion 102) of the surface 90 cooling from a molten form before the central portion (corresponding to the base portion 104). The direction of the concavity formed by the curved surface 106 and the base portion 104 is vertically upwards, which is parallel to the layering direction in which the object 90 was manufactured in this example. The presence of the sink causes the surface 92 to deviate from the corresponding (in this case planar) surface of the model on which the object is based. As discussed above, the measured surface data representing the at least a portion of the measured surface 92 may alternatively comprise image or 2D scan data representing the at least a portion of the measured surface 92.

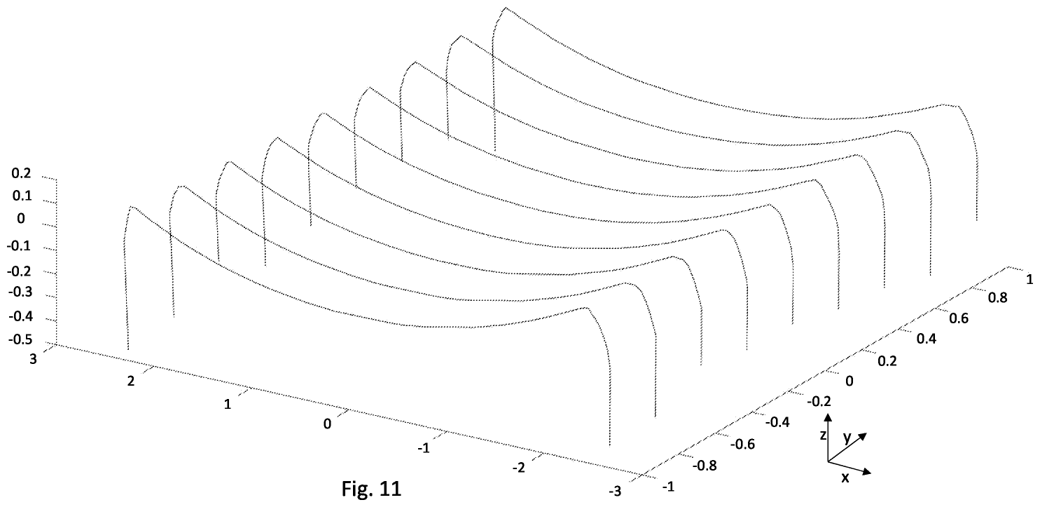

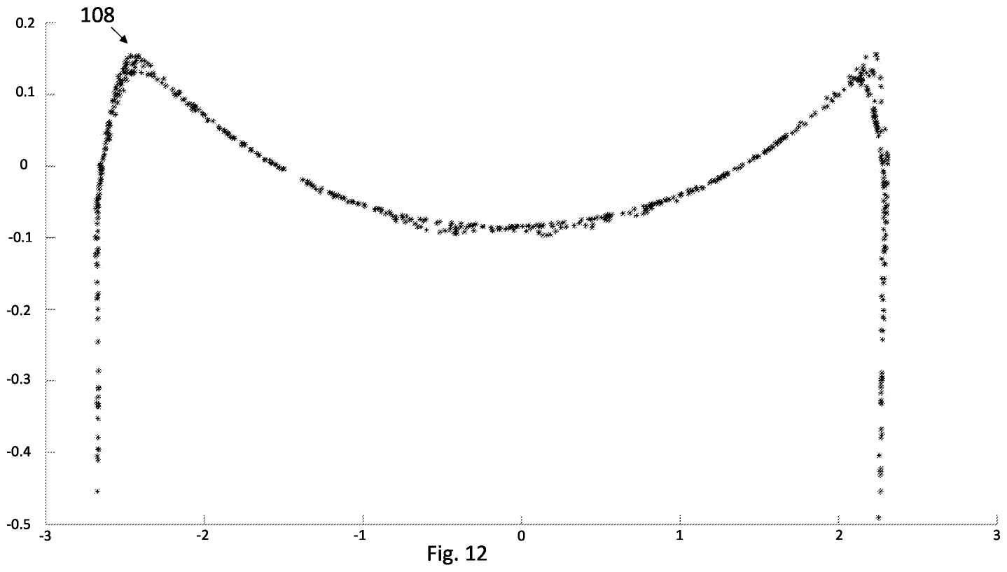

FIG. 11 shows an example series of cross-sections taken through the 3D scan data of FIG. 10 in the x-z plane of the co-ordinate system of FIG. 10, respective cross sections being spaced from each other along the y-axis. The cross-sections have generally similar shapes, but with some differences. This is illustrated in FIG. 12 which shows an example 2D superposition in the x-z plane of data points of the measured surface data 108 representing the at least a portion of the surface 92 of the object 90, the data points representing the said cross sections. FIG. 12 shows a significant amount of overlap between the data points from the different cross sections, but with some outlier data points. Some of the data points in FIG. 12 also arise from noise in the 3D scan data.

In order to determine a measurement surface for making a measurement relating to the object 90 which takes account of outlier data points, noise and the sink on the upper surface 92 of the object 90, a statistical analysis may be performed in respect of an interpretation direction as discussed above.

As discussed above, the interpretation direction may be predefined, for example based

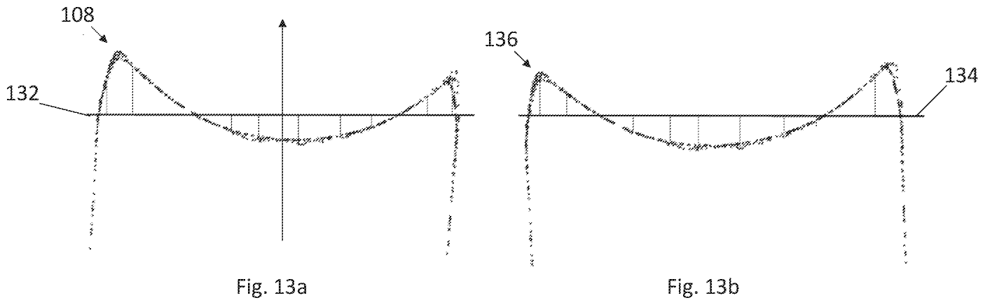

on the co-ordinate system of the data representing the measured surface 92 (e.g. the positive z-direction in FIGS. 10-12). As also discussed above, referring now to the examples of FIGS. 13a, 13b, in order to determine the interpretation direction, respective surfaces 132, 134 may be jointly fit to the measured surface data 108 representing the upper surface 92 of the object 90 (shown in FIG. 13a) and to data 136 representing a further (in this case upper) surface of the object 90 (shown in FIG. 13b). FIG. 13a shows superpositions in the x-z plane of data points of the measured surface data 108 representing the at least a portion of the surface 92 of the object the data points representing cross sections of the measured surface spaced from each other in the y-direction. FIG. 13b shows superpositions in the x-z plane of data points of the data 136 representing the at least a portion of the further surface of the object 90, the data points again representing cross sections of the measured surface spaced from each other in the y-direction. The further upper surface of the object 90 represented by data 136 also comprises a sink as shown in FIG. 13b.

As discussed above, the surfaces 132, 134 fit to the data 108, 136 representing the upper surfaces of the object 90 may be surfaces of predefined shape (e.g. the shapes of the surfaces may be predefined in the model on which the object is based). In this example, the model surfaces corresponding to the upper surfaces of the object are planar surfaces. As discussed above, the surface fits may be performed using any suitable surface fit method, such as a least-squares fit, such as an iterative least squares version of M-Estimation with Turkey weightings based on the previous iteration. The planar surfaces 132, 134 fit to the data 108, 136 representing the said upper surfaces may be jointly fit with parallel normals. The interpretation direction may be determined based on the parallel normals of planar surfaces 132, 134. For example, the interpretation direction may be selected to be parallel to the parallel normals of the planar surfaces 132, 134 (vertically upwards in the view shown in FIGS. 13a, 13b, illustrated by the arrow in FIG. 13a, e.g. corresponding to a direction of concavity of the sink surfaces).

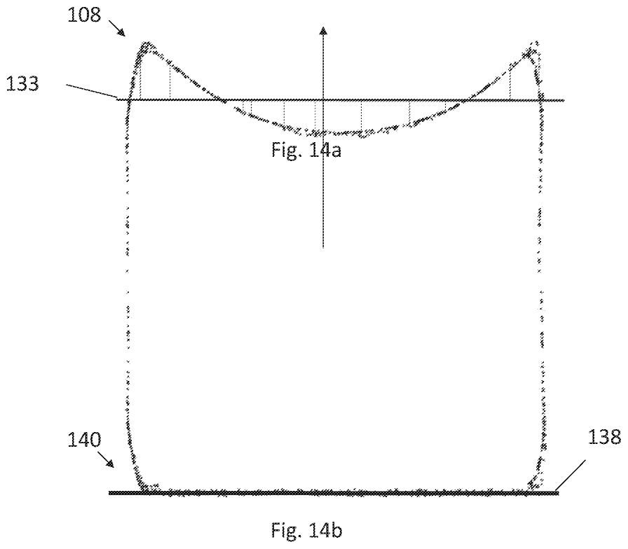

As both of the upper surfaces of the object 90 represented by data 108, 136 have sinks, there may be inaccuracy in the surfaces 132, 134 fit thereto, and thus in the interpretation direction. Accordingly, in an alternative example illustrated in the examples of FIGS. 14a, 14b, the interpretation direction may be determined based on surfaces 133, 138 jointly fit to the data 108, 140 representing the upper surface 92 of the object 90 and a further, in this case lower, surface 94 of the object 90. It may be that the lower surface 94 of the object 90 does not comprise a sink as shown in FIG. 14b, for example because the physical mechanisms causing the formation of the sink on the upper surface of the object 90 during cooling do not apply to the lower surface of the object 90. As such, it may be that the lower surface 94 better conforms to its corresponding surface of the model than the upper surface 92. As discussed above, the surfaces 133, 138 fit to the data 108, 140 representing the upper surface 92 and lower surface 94 of the object may be surfaces of predefined shape (e.g. the shapes of the surfaces may be predefined by corresponding surfaces of the model on which the object is based). In this example, the model surfaces corresponding to the upper surface 92 and the lower surface 94 of the object 90 are planar surfaces. As also discussed above, the surface fits may be performed using any suitable surface fit method, such as a least-squares fit, such as an iterative least squares version of M-Estimation with Turkey weightings based on the previous iteration. The planar surfaces 133, 138 fit to the surfaces 92, 94 may be jointly fit with a common normal. The interpretation direction may be determined based on the common normal of planar surfaces 133, 138. For example, the interpretation direction may be selected to be parallel to the common normal of the planar surfaces 133, 138 in this case (vertically upwards in the view shown in FIGS. 14a, 14b, illustrated by the arrow in FIG. 14a).

As discussed above, in other examples, the interpretation direction may be determined based (e.g. selectively) on a surface fit to the data representing the lower surface 94 of the object 90 or on any combination of surfaces fit to data representing a plurality of (e.g. upper, lower or upper and lower or angled) further surfaces of the object 90.

As discussed above, in an example statistical analysis, a data point of at least a portion of the measured surface data 108 may be identified corresponding to the k^{th} percentile data point of the at least a portion of the measured surface data 108 ordered in respect of the interpretation direction (e.g. the vertically upwards direction in the present example). For example, k may be set to 97.5. In this case, a data point may be identified in the measured surface data 108 which corresponds to the 97.5^{th} percentile data point of the at least a portion of the measured surface data 108 ordered in the vertically upwards direction. The measurement surface may be determined based on the said identified data point. For example, the measurement surface may be provided at a position along the interpretation direction based on the identified data point. For example, the measurement surface may be to pass through the said identified data point.

The measurement surface may have a predefined shape based on the shape of the model surface corresponding to the measured surface. As discussed above, the model surface corresponding to the measured surface 92 of the object may be a planar surface. Accordingly, it may be that the measurement surface is also a planar surface.

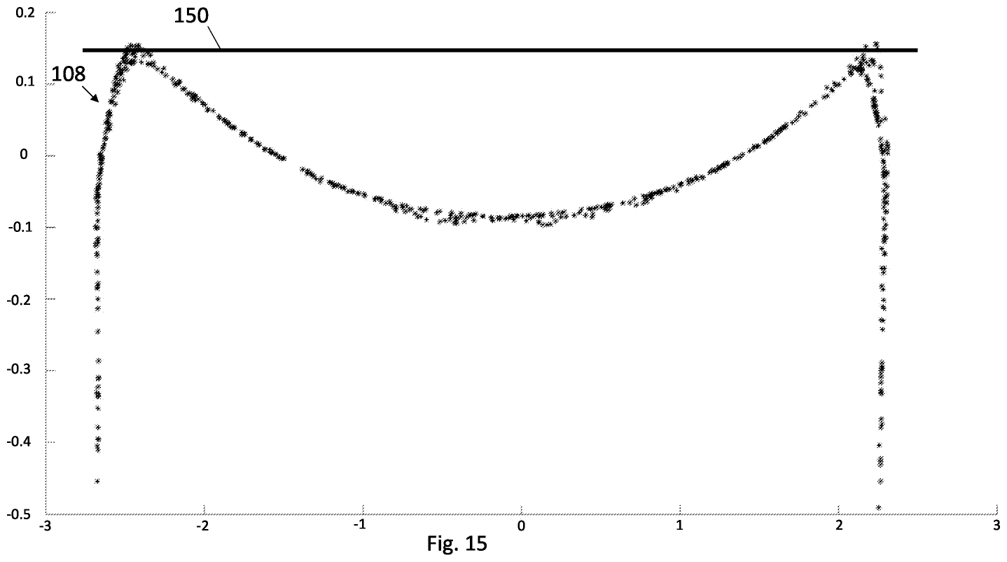

The orientation of the measurement surface may be selected depending on the interpretation direction. For example, it may be that the measurement surface is perpendicular to the interpretation direction. As illustrated in the example of FIG. 15, the measurement surface 150 may be a planar measurement surface perpendicular to the (in this example vertically upwards) interpretation direction, the planar measurement surface 150 passing through the (in this example) 97.5^{th} percentile data point of the at least a portion of the measured surface data 108 ordered in the (in this example vertically upwards) interpretation direction.

K may be selected such that the portion of the measured surface data representing the measured surface 92 offset beyond the measurement surface 150 in the (in this example, vertically upwards) interpretation direction comprises noise of the measured surface data, outlier data representing outlier portions of the measured surface data or both noise and outlier data. That is, k may be selected so that the measurement plane corresponds to an extent of the rim or edge portion of the sink with a reduced influence from noise and outlier data. It may be that measurements depending on the measurement surface 150 are more robust and reliable than, for example, measurements based on the 100^{th} percentile data point of the at least a portion of the measured surface data representing the measured surface 92 ordered in the (in this example vertically upwards) interpretation direction, which may correspond to noise or outlier data.

Any suitable alternative statistical analysis may be employed to determine the measurement surface 150, such as any of the alternative statistical analyses discussed herein.

As also discussed above, it may be that the measurement surface is determined by (e.g. automatically) determining an interpretation surface (e.g. a surface of predefined shape based on the model surface corresponding to the measured surface) and determining the measurement surface by providing the interpretation surface at a position depending on a statistical analysis of at least a portion of the measured surface data in respect of the interpretation direction. The interpretation surface may be a surface of predefined shape (e.g. determined from a surface of the model corresponding to the measured surface).

As discussed above, the interpretation surface may be based on reference surface data (e.g. image or scan data) representing at least respective portions of a reference surface or reference surfaces of the object. The reference surface or reference surfaces may comprise the measured surface, a further surface or further surfaces of the object other than the measured surface or the measured surface and a further surface or further surfaces of the object other than the measured surface of the object. The said further surface or at least one of the further surfaces may be or may not be parallel with the measured surface. The said further surface or at least one of the further surfaces may be or may not be aligned with the measured surface in the interpretation direction.

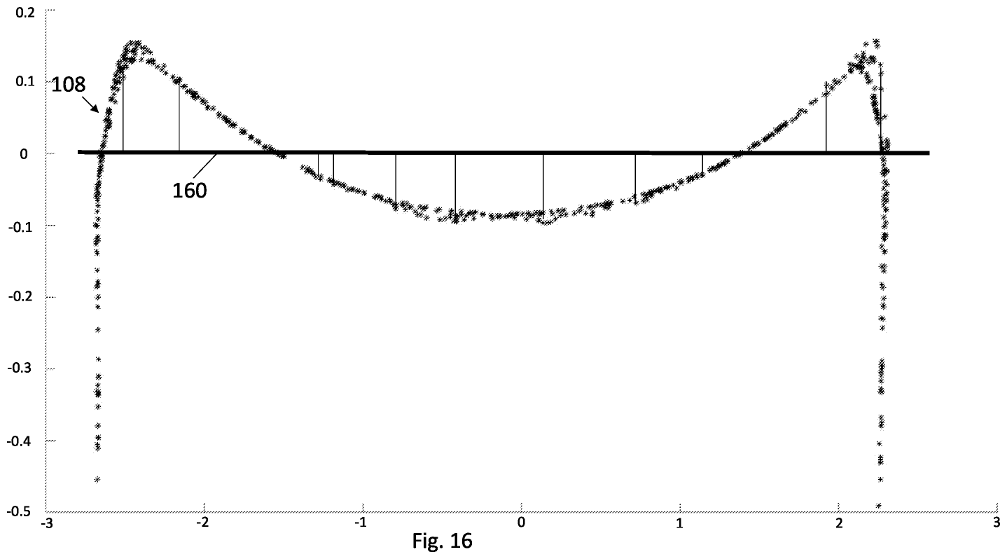

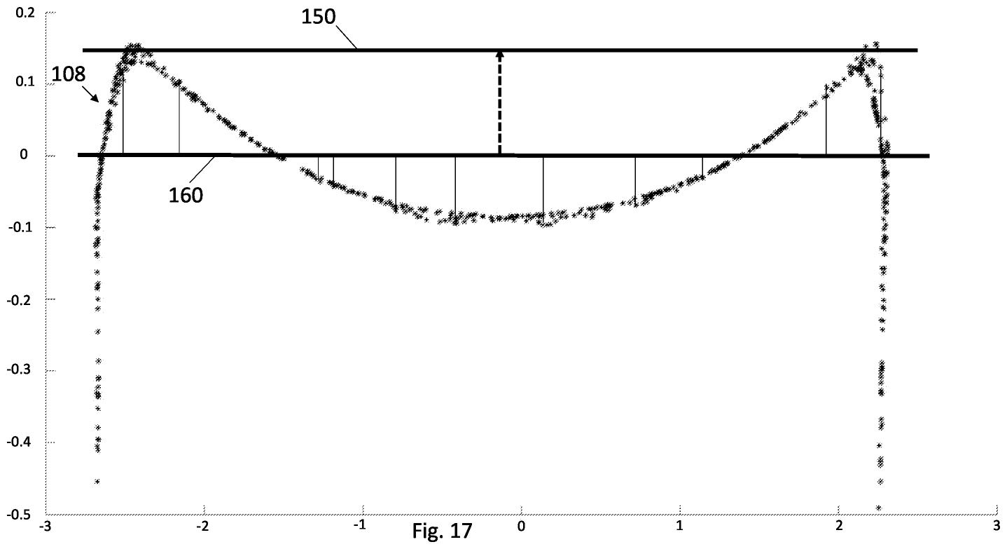

As shown in the example of FIGS. 16, 17, in an example, the interpretation surface 160 may be determined by fitting an (virtual) interpretation surface of predefined shape (e.g. based on the model surface corresponding to the measured surface) to the measured surface data 108 representing the measured surface 92 of the object 90. The interpretation surface 160 fit to the measured surface data 108 may be performed using any suitable surface fitting technique, such as a least-squares fitting technique (e.g. for minimising a least squares error function between the interpretation surface and the at least a portion of the measured surface data). In this case, it may be that the orientation of the measurement surface is determined based on the interpretation surface 160 fit to the measured surface data 108. It may be that the interpretation surface is inherently aligned with the measured surface data.

Alternatively, the interpretation surface 160 may be a suitably oriented surface of predefined (e.g. planar or non-planar) shape. For example, the interpretation surface 160 of predefined shape may be oriented depending on the interpretation direction. For example, the interpretation surface 160 of predefined shape may be oriented perpendicularly or substantially perpendicularly to the interpretation direction. In another example, the interpretation surface 160 may be oriented based on a surface fit or a plurality of surfaces fit (e.g. jointly fit) to further surface data (e.g. image or scan data) representing at least a portion of a further surface of the object 90 or at least respective portions of a plurality of reference surfaces of the object 90 other than the measured surface, or on surfaces (e.g. jointly) fit to both the at least a portion of the measured surface data and further surface data representing at least a portion of a further surface of the object 90 or at least respective portions of a plurality of reference surfaces of the object 90 other than the measured surface. The surfaces of the joint fit may be provided with a common normal or with parallel normals. The interpretation surface 160 may be provided with the same orientation as the fit surface or surfaces. Alternatively, if the fit surface or surfaces are not provided with the same orientation as the measured surface, it may be that the interpretation surface is determined by applying a (e.g. orientation) transformation to a said fit surface. The further surface or at least one of the further surfaces of the object 90 may be aligned or may not be aligned with the measured surface in the interpretation direction. In the latter case, as discussed above, it may be that a (e.g. alignment) transformation is applied to the surface fit to the reference surface data representing the further surface to determine the interpretation surface, for example so that the surface is aligned with the measured surface data.

The interpretation surface 160 may be positioned or translated along the interpretation direction based on a statistical analysis of at least a portion of the measured surface data 108, such as at least a selected portion of the measured surface data 108 offset beyond the interpretation surface 160 in the interpretation direction (e.g. vertically upwards in the example of FIGS. 16, 17) to provide the measurement surface 150. For example, a data point in the measured surface data 108 may be identified corresponding to the k^{th} percentile data point of offsets in the interpretation direction of (e.g. the selected portion of) the at least a portion of the measured surface data 108. As illustrated in the example of FIG. 17, the interpretation surface 160 may be positioned or translated along the interpretation direction such that it passes through the k^{th} percentile point of the offsets of (e.g. the selected portion of) the at least a portion of the measured surface data from the interpretation surface 160 in the interpretation direction. Similar results can be achieved from a statistical analysis of the measured surface data (including the portion of the measured surface data offset beyond the interpretation surface in a direction opposite to the interpretation direction) using a different value for k.

The interpretation direction may be determined based on the interpretation surface (e.g. the interpretation direction may be co-linear with or parallel to a normal to the interpretation surface). The interpretation direction may alternatively be determined by any of the other ways disclosed herein.

In the example shown in FIGS. 16, 17, where the interpretation surface 160 is a planar interpretation surface, it may be that the interpretation surface is not aligned with respect to the measured surface data 108 (e.g. for the said statistical analysis). For example, it may be that notional straight lines parallel to the interpretation direction passing through data points of the selected portion of the measured surface data do not pass through the interpretation surface 160. Similarly, it may be that the measurement surface based thereon is not aligned with respect to the measured surface data 108. Because the measurement surface is planar, virtual measurements may still be validly made between the measurement surface and data representing other surfaces of the object 90 in the interpretation direction, for example, based on a plane co-planar with the planar measurement surface.

Alternatively, for either planar or non-planar interpretation surfaces 160, and as shown in FIGS. 16, 17, it may be that the interpretation surface 160 is aligned with respect to the measured surface data 108, for example to perform the said statistical analysis of the selected portion of the measured surface data 108. For example, notional straight lines parallel to the interpretation direction passing through data points of the selected portion of the measured surface data may pass through the interpretation surface. Similarly, it may be that the measurement surface based thereon is aligned with respect to the measured surface data. Particularly for non-planar surfaces, this alignment allows offsets of the measured surface data to be determined relative to the (e.g. predefined) shape of the interpretation surface for the said statistical analysis.

For example, FIG. 18 shows an example non-planar interpretation surface 180 (e.g. of predefined shape) and measured surface data 182 representing at least a portion of a surface of an object, the measured surface data 182 being offset beyond the non-planar interpretation surface 180 in the interpretation direction (vertically upwards in the example of FIG. 18). The non-planar interpretation surface 180 may be aligned with the measured surface data 182 such that notional straight lines parallel to the interpretation direction passing through data points of the selected portion of the measured surface data 182 pass through the interpretation surface 180. The interpretation surface 180 may be provided at (e.g. translated to) a position depending on a statistical analysis performed based on offsets of the measured surface data 182 relative to corresponding portions of the aligned interpretation surface 180 in the interpretation direction.

For example, the method may comprise identifying a data point corresponding to a k^{th} percentile data point of the at least a portion of the measured surface data 182 relative to the corresponding portions of the interpretation surface ordered in respect of the interpretation direction. The method may comprise determining the measurement surface 184 based on the identified data point. For example, it may be that the measurement surface 184 is to pass through the identified data point. For example, it may be that the interpretation surface 180 is translated along the interpretation direction such that it passes through the identified data point in order to provide the measurement surface 184.

Although the k^{th} percentile point is discussed above, the description could be readily adapted to any suitable statistical analysis or metric, such as any of the statistical analyses or metrics disclosed herein.

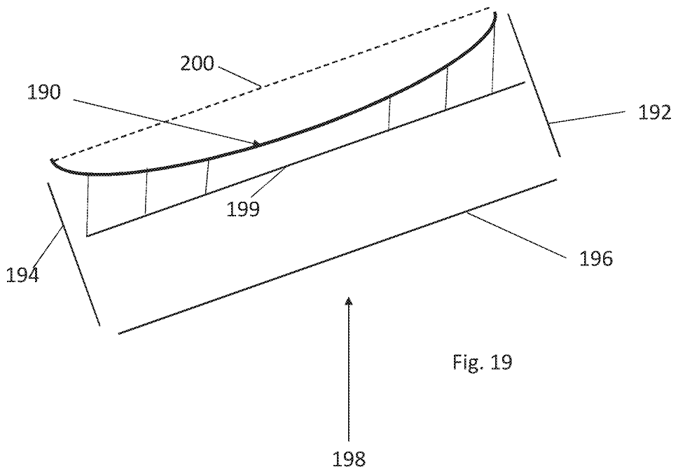

FIG. 19 shows an example in which an object manufactured by an additive manufacturing process is provided with a surface 190, the surface 190 having a sink. The object may be manufactured according to a model. The surface 190 may correspond to a planar surface of the model. The planar surface of the model may be angled (e.g. at a non-zero angle) with respect to the layering direction in which the object is manufactured (which may correspond to the vertically upwards direction in FIG. 19). Lateral surfaces 192, 194 extend between the surface 190 and a base surface 196 opposite the surface 190. The lateral surfaces 192, 194 and base surface 196 may correspond to planar surfaces of the model on which the object is based. The lateral surface 192 and the base surface 196 (which do not have sinks in this example) may conform better to the planar surface of the model than the surface 190 (which deviates from the corresponding model surface primarily due to the sink). It may be that the interpretation direction is to align with the layering direction of the additive manufacturing process. In this case, it may be that the interpretation direction is not co-linear or parallel with a normal to a surface fit to data representing the surface 190 or indeed to data representing the lateral or base surface 192, 194, 196.

As discussed above, the interpretation direction may be determined more accurately based on surfaces fit to data representing the lateral surface 192 and the base surface 196 as they conform better to the corresponding surfaces of the model. Accordingly, the interpretation direction in this case may be determined by: fitting (e.g. planar) surfaces to 2D or 3D image or scan data representing the lateral surface 192 and the base surface 196; determining normals to the surfaces fit to the lateral and base surfaces 192, 196; and determining the interpretation direction based on the normals to the surfaces fit to the lateral and base surfaces 192, 196. For example, a vertical interpretation direction 198 may be determined based on the normals to the surfaces fit to the lateral and base surfaces 192, 196 based on a predetermined relationship (e.g. based on the model) between the lateral and base surfaces 192, 196 (or normals thereto) and the (in this case vertical) interpretation direction.

As before, an interpretation surface 199 may be determined by any of the ways described herein, and the interpretation surface 199 may be translated in or positioned along the interpretation direction based on a statistical analysis in the interpretation direction 198 to provide the measurement surface 200. Measurements may be made depending on the measurement surface 200.

The measured surface data representing at least a portion of the measured surface, and the reference surface representing the reference surface or the plurality of reference surfaces (where provided), may be derived from data representing at least a portion of the object, the said portion comprising the said measured surface and the said reference surface or reference surfaces. In order to derive the measured surface data and the reference surface data (where provided), a correspondence between the model on which the object is based and the data representing the object may be performed. For example, the correspondence may be based on matching shapes of surfaces of the model to the measured surface data.

Referring to the example of FIG. 4, there is shown a flow chart of a method, indicated generally by the reference numeral 40, for identifying a surface having a predefined shape (such as a shape of a surface predefined in a model) in data, such as 2D or 3D image or scan data, representing at least a portion of an object. The method 40 may be for aligning the model on which an object is based with data, such as 2D or 3D image or scan data, representing at least a portion of the object. The method 40 may be (e.g. automatically) performed by processing circuitry 22 of the apparatus 20 or the method 40 may be performed separately.

The method 40 may be used to identify data representing a measured surface (or a further surface other than the measured surface) of an object based on data representing at least a portion of an object and a model on which the object is based. The measured surface (or further surface) may correspond to a surface of a model having the said predefined shape.

At 42, the method may comprise analysing the model according to which the object is manufactured. The model may comprise a computer model, such as a (e.g. 3D) CAD model. For example, the model may comprise a three-dimensional polygon mesh model of the object. The analysis of the model may be to identify at least one sub-mesh representing at least one predefined geometric shape.

At 44, the method 40 may comprise aligning the model with image or scan data (e.g. 3D scan data) representing the at least a portion of the object.

At 46, the method 40 may comprise identifying the position of the at least one predefined geometric shape in the image or scan (e.g. 3D scan) data based on the alignment to thereby identify a surface having the predefined shape.

When aiming to identify a geometric shape in data representing an object, carrying out an analysis of the (e.g. polygon mesh) model of the object may be more efficient than analysing image or scan data representing the object. The model does not include noise that may be present in image or scan data representing the object and may comprise a smaller number of data points. This more concise geometric representation leads to a reduced processing load.

It is assumed in the following description that the model is a polygon mesh model, but the description may be adapted for other types of computer model. At 42, the polygon mesh model of the object may be (e.g. automatically) analysed to identify sub-meshes that correspond to certain geometric shapes that may be present in the object. The geometric shapes may also be referred to as geometric primitives, as they may be considered to represent a form or shape from which the shape of the object is composed. It may be that no user input is provided to determine the geometric shapes of interest in the model of the object. Furthermore, it may be that no additional design is performed in the creating the model to facilitate identifying the geometric shapes. For example, it may be that no design input is provided to identify or specify reference locations in the model. The method may comprise, at 42, identifying one, some, or all instances of one particular geometric shape, or identifying one, some, or all instances of a selection of geometric shapes. Such shapes may include: planar shapes, including irregularly shaped planar shapes and regularly shaped planar shapes; non-planar shapes such as curved shapes (e.g. spheres or cylinders); shapes representing combinations of planar shapes and non-planar shapes, for example polyhedrons such as any of tetrahedrons, cubes, cuboids, prisms. Generally, if a shape can be modelled, examples of that shape can be identified in the polygon mesh model.

Analysing the polygon mesh model to identify at least one sub-mesh representing a geometric shape may comprise identifying the at least one sub-mesh according to a stored definition. The stored definitions may be stored in memory 24 of apparatus 20. Suitable definitions that may be stored include any of: a definition of a planar surface, a definition of a sphere, a definition of a cylinder, a definition of a cuboid, a definition of another polyhedron or other polyhedrons, other definitions. In general, the identification of the sub-meshes may be automatic (e.g. with no user input), however, in certain examples, a user may choose which geometric shapes to search for in the model. In a polygon mesh model having meshes with vertices repeated for each polygonal face for which they are a part, the method may comprise pre-processing the polygon mesh model to combine repeated vertices and their references in the polygons of the mesh.

An analysis of the model may be directed to identifying significant planes within the object. A plane may be identified as a connected sub-mesh where the faces within the sub-mesh share a normal direction. Identifying significant planes may include identifying sub-meshes where faces within the sub-mesh have an area above a certain threshold. For example, a suitable threshold area may be 10 mm² for an object of linear dimension 100 mm. Identifying significant planes may include identifying sub-meshes where faces within the sub-mesh have an aspect ratio below a certain value, here the aspect ratio is defined as the ratio of the longest and shortest orthogonal dimensions of the sub-mesh defining the plane. For example, a suitable aspect ratio may be 5. These thresholds may be scaled as the dimensions of the object are scaled.

An analysis of the model may be directed to identifying significant spheres or regular cylinders within the object. A sphere may be defined by four non-planar vertices in a polygon mesh model. For each face within the polygon mesh model of the object, a subset of four neighbouring or included non-planar vertices may be recruited that can be used to calculate the centre and radius for a sphere on whose surface that subset of vertices is located. Once the parameters (centre and radius) of the sphere have been calculated, other vertices in the augmented polygon mesh may be tested for agreement with the calculated parameters. The distance of the vertex points from the centre may be calculated and compared to the radius of the sphere. If that distance is within a threshold, the vertex may be considered to be located on the sphere surface. For each face in the polygon mesh model, possible spheres including that face may be determined by identifying sets of neighbouring or included non-planer vertices that define a sphere, and then checking remaining vertices for inclusion in that sphere. Multiple potential spheres may be analysed for the face. This process may be repeated for each face in the polygon model mesh. Significant spheres or sphere portions may be identified in the augmented polygon mesh model as a sub-mesh of connected faces that form the surface of the sphere or sphere portion. Spheres or sphere portions may be considered significant if the surface area and solid angle of the sphere is above a certain threshold. The solid angle may be approximated from the sum of the areas of the faces of the sub-mesh divided by the radius squared. Fora sphere portion, those having a solid angle larger than a π/2, representing ⅛^{th} of a complete sphere, may be considered significant. As previously, a minimum threshold surface area of 10 mm² may be applied to the surface area of the sphere itself.

Cylinders may be identified in the polygon mesh model in a similar manner. Cylinders may be defined by five or six non-planar points. For each face in the polygon mesh model, neighbouring vertices are analysed to check for their ability to define a cylinder. If a potential cylinder is identified, the remaining vertices are checked to see if they form part of the surface of that cylinder. For a cylinder, the perpendicular distance from the vertex point to the axis of the cylinder is to be calculated, rather than the distance used for the sphere. Cylindrical sub-meshes may be considered significant if their length along the axis of the cylinder is significant with respect to its radius and their surface area is above a threshold. For example, a surface area above 10 mm² for an object of overall linear dimension 100 mm would be a suitable threshold for significance.

Once the sub-meshes representing the geometric shapes have been identified, the polygon mesh model may be augmented with the geometric shape data to provide an updated polygon mesh model, which may also be referred to as an augmented polygon mesh model. The augmented mesh model may comprise the original polygon mesh model and a list of geometrical primitives, each of which includes an array of references to the constituent polygon faces. Each element in the list of geometrical primitives make explicit their form, for example planar surface, sphere, cylinder, and the like, and may also include any relevant parameters. The faces and by reference the included vertices of each identified geometric shape may be referenced according to the geometric shape instance of the augmented polygon mesh model. In this way, the processing of the polygon mesh model to generate the augmented polygon mesh model may be considered a classification process, where each vertex and face for a particular geometric shape are classified into a category or group.

Referring now to the example of FIG. 5, there is shown a block diagram of an augmented model 50. The augmented model 50 comprises the model 52 (such as the polygon mesh model) and the (e.g. geometric) shape information 54 derived at 42 of the method 40 of FIG. 4.

Referring back to the example of FIG. 4, at 44, the augmented model may be aligned with the data representing the at least a portion of the object, for example in order to identify the measured surface data and the reference surface data (where provided).

The data representing the at least a portion of the object may be represented as: a polygon mesh; as a point cloud of data points on the surface of the scanned object; or in another suitable format. If using a point cloud representation, the data representing the at least a portion of the object may comprise the locations of a plurality of (e.g. 3D) points on the surface of the object. Data representing the at least a portion of the object in the form of a polygon mesh may include the locations of (e.g. 3D) vertex points on the surface of the object and the edges connecting the vertex points. The data representing the at least a portion of the object may be obtained in any suitable manner. The data representing the at least a portion of the object may be generated by combining multiple 2D or 3D images or scans of multiple views of the object. Alternatively, the data representing the object may be obtained from a single 2D or 3D view.

The aligning of the model and the (e.g. image or scan) data representing the at least a portion of the object may comprise providing an approximate alignment between the model and the data representing the at least a portion of the object. As such, the alignment between the model and the data representing the at least a portion of the object may be considered an approximate alignment. For example, the alignment may be accurate to within 1 mm and 1°. The method 40 may comprise adjusting the data representing the at least a portion of the object, for example to bring it into the same coordinate frame system as the augmented model. An approximate alignment may be acceptable as it may be used as a starting point from which to identify the geometric shapes in the data representing the at least a portion of the object. The alignment allows the recruitment of points in the data representing the at least a portion of the object with respect to each of the geometric shapes identified in the augmented model. Examples of mesh and point cloud alignment are (Winkelbach, S., Molkenstruck, S., and Wahl, F. M. (2006), Low-cost laser range scanner and fast surface registration approach, In Pattern Recognition, pages 718-728. and Azhar, F., Pollard, S. and Adams, G. (2019) ‘Gaussian Curvature Criterion based Random Sample Matching for Improved 3D Registration’ at VISAPP) but the alignment described herein is not limited to these examples.

At 46 of method 40, the position of the geometric shapes in the augmented model may be identified in the data representing the at least a portion of the object. Identifying the position of the at least one geometric shape in the data representing the at least a portion of the object may comprise associating a selection of the data points of the data representing the at least a portion of the object with the geometric shape closest thereto. As such, the selected data points of the data representing the at least a portion of the object may be associated with the closest geometric shape of the augmented model. The identifying process may be understood to refer to a recruitment process where a selection of points in the data representing the at least a portion of the object are recruited into each geometric shape. Each point in the data representing the at least a portion of the object may be associated with its closest polygon in the augmented model. For those faces in the data representing the at least a portion of the object that are identified as belonging to geometrical shapes in the augmented model data, the data points of the data representing the at least a portion of the object that are associated with them are thus associated with the corresponding geometrical shape instance. Identifying the position of the at least one geometric shape in the data representing the at least a portion of the object may further comprise processing the data points of the data representing the at least a portion of the object associated with a geometric shape in the model to locate a corresponding geometric shape in the data representing the at least a portion of the object.

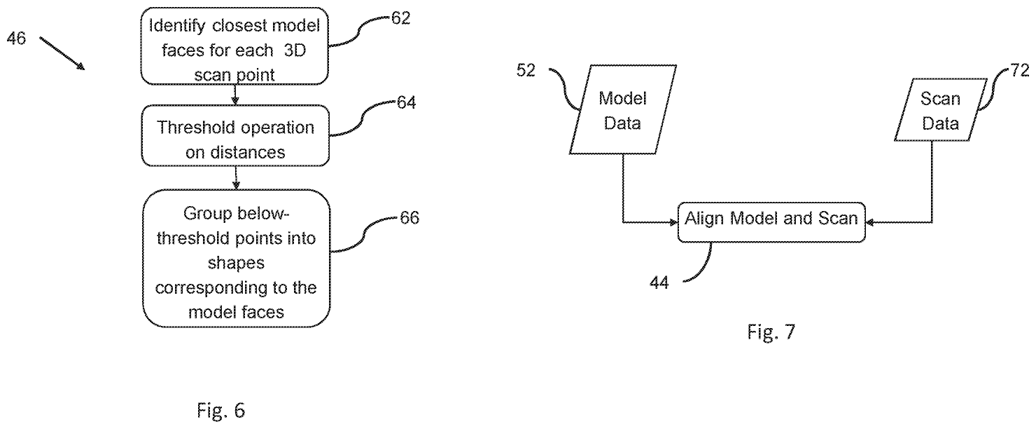

FIG. 6 shows an example implementation of block 46. At 62, the distances from some or all of the points in the data representing the at least a portion of the object to the (e.g. polygonal) faces of the (e.g. polygon mesh) model may be calculated. Next, at 64, a threshold operation may be carried out to identify the closest (e.g. polygon) faces for each point in the data representing the at least a portion of the object that are within a closest distance threshold to the respective face. The points of the data representing the at least a portion of the object corresponding to each respective face may be further restricted to selectively include those having a perpendicular to the face lying within the boundary of the (e.g. polygon of the) face. Then the points in the data representing the at least a portion of the object with sub-threshold distance may be thus grouped as geometric shapes corresponding to the geometric shapes identified in the augmented model, based on the face in the model to which the point was closest. The group associated with the measured surface may be provided as the measured surface data, while the groups associated with the reference surfaces may be provided as the reference surface data (where provided).

The method 40 provides for fully automated identification of surfaces from (e.g. image or scan) data representing at least a portion of the object. As the process of FIG. 1 may also be automated, the object measurement process can also thus be fully automated. Generating an object-specific inspection routine can be avoided, even when the object has a surface having a surface deviation compared to the corresponding surface of the model, and/or highly customisable manufacturing processes. Measurements can be performed without predefining any specific datums within the model. The estimated geometric shapes in the data representing the at least a portion of the object (such as the measured surface or the further surfaces), for example, in combination with the method of FIG. 1, allow recovery of measurements such as the separation and relative orientation of the geometric shapes in the object. The measurements available from the method are not limited to some dimensions of the object, but all aspects of the instance of the object may be measured.

Measurements relating to the object based on the measurement surface may comprise distance or displacement measurements between pairs of surfaces. For example, the measurements may comprise plane-to-plane or surface-to-surface or sink edge-to-surface measurements, such as the (e.g. perpendicular) distance between planes or surfaces or between a sink edge (e.g. based on the measurement surface) and a further surface of the object. It is also possible to measure the relative orientation of non-grouped planes or surfaces.

These measurements may then be compared with corresponding measurements from the model for an indication of the accuracy of the object. As discussed, measurements relating to the object based on the determined measurement surface can be further analysed to provide automatic print control parameters such as scale and offset which can in turn be fed back into a manufacturing process to optimise or control the manufacturing process, such as by way of updates to the additive manufacturing apparatus control and calibration parameters or (e.g. individualized) pre-compensation of the model.

Scale and offset may be referred to as non-rigid deformation occurring in the object. Each object manufactured by an additive manufacturing apparatus (e.g. 3D printer) has roughly constant scale and offset but they may change depending where on a print bed of the additive manufacturing apparatus (e.g. 3D printer) the object is printed.

Making a measurement relating to the object based on the measurement surface may comprise calculating the scale and offset parameters of the manufacturing process for the object. The printed object may be scaled differentially in the x, y and z directions with respect to the print bed and each of these scales may differ from the unity value that allows an instance of the object to be printed at its specified size. These scale parameters can be garnered from the appropriate components of measurements between recovered geometrical primitives (e.g. between the derived measurement surface and a reference surface of the object).

The offset may also be referred to as the erosion and dilation of the surface material. For example, the thickness of the walls of a printed object may all be too thick if the offset is in the form of a dilation or too thin if the offset is in the form of an erosion. The size of the offset may also differ in each of the x, y and z directions. For a situation where the object is manufactured through additive manufacturing, on a print bed, and the object is aligned with the x, y, z axes of the print bed, it is possible to directly calculate the scale and offset by solving a simple linear relationship. In each dimension, scale and offset are the gradient and offset in the following linear equation:

yᵢ=xᵢm+oᵢc (1)

where x, and y, are the model and scanned data measurements for this axis respectively; o, is an offset inclusion parameter that is set to 1 where the two surfaces involved in a measurement are surfaces with opposite polarity (e.g. facing vertically upwards and vertically downwards respectively) and 0 otherwise, m is the gradient (scale) and c the offset (dilation/erosion of the surface material). The above equation can be represented as a system of equations,

$$Y = [ X O ] [ \begin{matrix}m \\ c\end{matrix} ] \qquad ( 2 )$$

which may be solved using a linear least squares method. Similar equations can be used in the case where the surfaces are not directly aligned with major axes of the printer.

An example type of measurement may include an offset, this type may be considered as “calliper type” measurements, for example between a pair of planes of opposite polarity or estimates of the diameter of a sphere. A second type of measurement does not include an offset, for example step heights where both surfaces have the same offset and it is not discernible, or distances between sphere centres.

It may be helpful when fitting planes to ignore regions close to the edge of the plane by shrinking the individual surfaces or planes that form the polygon mesh model. This introduces a guard band around the points that are recruited form a specific plane and makes it less likely to recruit points belonging to adjacent surfaces in the presence of small residual misalignment of the polygon mesh model against the scanned point cloud.

FIG. 7 is a block diagram showing the data inputs to aligning block 44. The aligning block 44 receives an augmented polygon mesh model 110 in which a geometric shape or a plurality of geometric shapes have been identified. It further receives data (e.g. 3D scan data) representing the at least a portion of the object.

Updated control or calibration parameters of the additive manufacturing apparatus, updated pre-compensations applied to the model or updated control or calibration parameters and pre-compensations may be determined independently on respective spatial dimensions of the object. It may be that the updated calibration parameters of the additive manufacturing apparatus, updated pre-compensations applied to the model or updated control or calibration parameters and pre-compensations determined based on the derived measurement surface are updated control or calibration parameters, updated pre-compensations applied to the model or updated control or calibration parameters and pre-compensations in a spatial dimension aligned with the interpretation direction.

A further object may be manufactured according to the model by the additive manufacturing apparatus based on the updated control or calibration parameters, the updated pre-compensations or the updated control or calibration parameters and pre-compensations. The further object may be more accurately manufactured (e.g. with a higher quality) than the said object 90.

It may be that the method comprises (e.g. the processing circuitry 22 of the apparatus causing adjustment of a control or calibration parameter of an additive manufacturing apparatus by which the object was manufactured; causing adjustment of a pre-compensation factor to be applied to the model. It may be that the method comprises (e.g. the processing circuitry 22 of the apparatus 20) causing an additive manufacturing apparatus to manufacture another object based on the adjusted control or calibration parameters, the adjusted pre-compensation factors or both the adjusted control or calibration parameters and the adjusted pre-compensation factors.

It may be that the method comprises (e.g. the processing circuitry 22 of apparatus 20) determining the accuracy of the manufacturing technique, or determining a quality metric relating to the object, depending on (e.g. the measurement made relative to) the measurement surface. It may be that the method comprises (e.g. the processing circuitry 22 of apparatus 20) providing an output based on the said determined accuracy or determined quality metric.

It may be that a graphical user interface is presented to a user on a display showing differences (e.g. by way of a color coding) between the measurement surface and the measured surface data. It may be that the above described method is repeated for a plurality of measurement surfaces of the object. It may be that the graphical user interface shows differences (e.g. by way of color coding) between each of the plurality of measurement surfaces of the object and the respective measured surface data on which they are based.

The above-mentioned description is applicable to objects other than the example snowflake object 90.

In this specification, the phrase “at least one of A or B” and the phrase “at least one of A and B” should be interpreted to mean any one of the plurality of listed items A, B, etc. or any plurality of the plurality of listed items A, B, etc., taken jointly and severally in any and all permutations.

Where functional units are described as circuitry, such as the controller 88, for example, the circuitry may be general purpose processor circuitry configured by program code to perform specified processing functions. The circuitry may also be configured by modification to the processing hardware. The configuration of the circuitry to perform a specified function may be limited exclusively to hardware, limited exclusively to software, or a combination of hardware modification and software execution. Program instructions may be used to configure the logic gates of general purpose or special purpose processor circuitry to perform a processing function.

Circuitry may be implemented, for example, as a hardware circuit comprising processors, microprocessors, circuits, circuit elements (e.g., transistors, resistors, capacitors, inductors, and so forth), integrated circuits, application specific integrated circuits, programmable logic devices, digital signal processors, field programmable gate arrays, logic gates, registers, semiconductor devices, chips, microchips, chip sets, and the like.

The processors may comprise general purpose processors, network processors that process data communicated over a computer network, or other types of processor, including reduced instruction set computers or complex instruction set computers. Each processor may have a single or a multiple core design. Multiple core processors may integrate different processor core types on the same integrated circuit die.

The controller described herein may be implemented in whole or in part by machine-readable program instructions. Machine-readable program instructions may be provided on a transitory medium, such as a transmission medium, or on a non-transitory medium, such as a storage medium. These machine-readable instructions (computer program code) may be implemented in a high level procedural or object oriented programming language. However, the program may be implemented in assembly or machine language, if desired. In any case, the language may be a compiled or interpreted language, and combined with hardware implementations.

Examples of the present disclosure are applicable for use with all types of semiconductor integrated circuit (IC) chips. Examples of these IC chips include but are not limited to processors, controllers, chipset components, programmable logic arrays, memory chips, and network chips. Any of the components described herein may be embodied as a System On Chip (SOC) device. A SOC may include, for example, a Central Processing Unit core, a Graphics Processing Unit core, an Input/Output interface, and a memory controller. In some examples, a SOC and its components may be provided on an integrated circuit die or on a plurality of integrated circuit dies; for example, they may be packaged into a single semiconductor device.

The disclosure also extends to the following examples.
Example 1: A (e.g. computer-implemented) method of making a measurement relating to an object may be provided. The object may be an object manufactured according to a model, for example by additive manufacturing. The object may have a measured surface comprising a surface deviation relative to a corresponding surface of the model. The method may comprise obtaining measured surface data representing at least a portion of the measured surface comprising the said surface deviation. The method may further comprise (e.g. automatically) determining (e.g. by a computer) a (e.g. virtual) measurement surface corresponding to the measured surface of the object by performing a statistical analysis of at least a portion of the measured surface data (e.g. selectively) in respect of an (e.g. virtual) interpretation direction such that a portion of the measured surface data is offset from (or beyond) the measurement surface in the interpretation direction. The method may further comprise (e.g. automatically) making (e.g. by a computer) a measurement relating to the object depending on the measurement surface.
Example 2: The method of example 1 comprising determining the interpretation direction depending on a (e.g. virtual) surface fit to reference surface data representing at least a portion of a reference surface of the object. The method may comprise fitting the said (e.g. virtual) surface to the reference surface data representing the reference surface.
Example 3: The method of example 2 wherein the reference surface of the object comprises a surface of the object other than the measured surface.
Example 4: The method of example 3 wherein the reference surface of the object comprises a reference surface on an opposite side of the object from the measured surface.
Example 5: The method of example 3 or example 4 wherein the reference surface deviates less from (or better conforms to) a corresponding reference surface of the model than the measured surface deviates from (or conforms to) the corresponding measured surface of the model.
Example 6: The method of any one of examples 2 to 5 comprising determining the interpretation direction depending on (e.g. virtual) surfaces fit to reference surface data representing at least respective portions of a plurality of reference surfaces of the object.
Example 7: The method of example 6 wherein the respective surfaces are jointly fitted to the reference surface data representing the said plurality of reference surfaces. The method may comprise jointly fitting the respective surfaces to the said reference surface data representing the said plurality of reference surfaces.
Example 8: The method of example 7 wherein the respective surfaces fit to the reference surface data representing the reference surfaces have a common normal or parallel normals.
Example 9: The method of example 8 wherein the interpretation direction is based on the said common or parallel normals.
Example 10: The method of any one preceding example wherein determining the measurement surface based on the said statistical analysis comprises identifying a data point corresponding to a k^{th} percentile data point of the at least a portion of the measured surface data ordered in respect of the interpretation direction and determining the measurement surface depending on the identified data point. It may be that k is a predefined value.
Example 11: The method of any one preceding example wherein determining the measurement surface by performing the said statistical analysis comprises: orienting, or aligning and orienting, an interpretation surface with respect to the measured surface data; and providing the interpretation surface at a position along the interpretation direction depending on the statistical analysis.
Example 12: The method of example 11 wherein the interpretation surface is of a predefined (e.g. planar or non-planar) shape.
Example 13: The method of example 11 or example 12 comprising determining the measurement surface based on the interpretation surface.
Example 14: The method of any one preceding example wherein determining the measurement surface by performing the said statistical analysis comprises determining the measurement surface based on a statistical analysis of a restricted portion of the measured surface data corresponding to a predefined portion of the measured surface.
Example 15: The method of any one preceding example wherein the said surface deviation of the measured surface comprises a sink.
Example 16: The method of any one preceding example wherein the surface deviation of the measured surface comprises a curved portion.
Example 17: The method of example 16 wherein the interpretation direction is parallel or substantially parallel to a direction of concavity of the said curved portion.
Example 18: The method of any one preceding example wherein the measurement surface has an orientation based on the interpretation direction.
Example 19: The method of any one preceding example further comprising any of the following based on the said measurement: causing adjustment of a control or calibration parameter of an additive manufacturing apparatus by which the object was manufactured; causing adjustment of a pre-compensation factor to be applied to the model.
Example 20: The method of example 19 further comprising causing an additive manufacturing apparatus to manufacture another object based on the adjusted control or calibration parameter, the adjusted pre-compensation factor or both the adjusted control or calibration parameter and the adjusted pre-compensation factor.
Example 21: The method of any one preceding example wherein the said portion of the measured surface data offset from (or beyond) the measurement surface in the interpretation direction (e.g. selectively) comprises noise of the measured surface data, outlier data representing outlier portions of the measured surface data or both noise and outlier data.
Example 22: A (e.g. computer-implemented) method may be provided. The method may comprise: obtaining measured surface data representing at least a portion of a measured surface of an object. The said at least a portion of the measured surface of the object may comprise a surface deformation. The method may comprise (e.g. automatically) determining (e.g. by a computer) a statistical metric based on a statistical analysis of at least a portion of the measured surface data in respect of an interpretation direction. The method may comprise (e.g. automatically) determining (e.g. by a computer) a virtual measurement surface depending on the statistical metric. The virtual measurement surface may correspond to the measured surface of the object. The method may comprise making a measurement depending on the virtual measurement surface. It may be that the method comprises determining the virtual measurement surface depending on the statistical metric such that a portion of the measured surface data is offset from (or beyond) the measurement surface in the interpretation direction.
Example 23: The method of example 22 further comprising determining the interpretation direction based on a virtual surface based on (e.g. fit to) reference surface data representing at least a portion of a reference surface of the object. The method may comprise fitting the said virtual surface to the said reference surface data.
Example 24: The method of example 23 wherein the reference surface of the object comprises a surface of the object other than the measured surface.
Example 25: The method of any one of examples 22 to 24 wherein determining the statistical metric comprises determining a k^{th} percentile data point of the at least a portion of the measured surface data in respect of the interpretation direction.
Example 26: An apparatus may be provided. The apparatus may comprise processing circuitry. The processing circuitry may be to obtain measured surface data representing at least a portion of a measured surface of an object, the said at least a portion of the measured surface of the object comprising a surface deformation. The processing circuitry may be further to (e.g. automatically) determine a statistical metric based on a statistical analysis of at least a portion of the measured surface data in respect of an interpretation direction. The processing circuitry may be further to (e.g. automatically) determine a virtual measurement surface depending on the statistical metric. The virtual measurement surface may correspond to the measured surface of the object. The processing circuitry may be further to (e.g. automatically) make a measurement depending on the virtual measurement surface. It may be that the processing circuitry is to determine the virtual measurement surface depending on the statistical metric such that a portion of the measured surface data is offset from (or beyond) the measurement surface in the interpretation direction.
Example 27: The apparatus of example 26 wherein the processing circuitry is further to determine the interpretation direction based on a virtual surface based on reference surface data representing at least a portion of a reference surface of the object. The processing circuitry may be to fit the said virtual surface to the said reference surface data.
Example 28: The apparatus of example 27 wherein the reference surface of the object comprises a surface of the object other than the measured surface.
Example 29: The apparatus of any one of examples 26 to 28 wherein determining the statistical metric comprises determining a k^{th} percentile data point of the at least a portion of the measured surface data in respect of the interpretation direction.
Example 30: An apparatus may be provided. The apparatus may be to make a measurement relating to an object. The object may be manufactured according to a (e.g. computer) model. The object may have a measured surface comprising a surface deviation relative to a corresponding surface of the model. The apparatus may comprise processing circuitry. The processing circuitry may be to (e.g. automatically) obtain measured surface data representing at least a portion of the measured surface comprising the said surface deviation. The processing circuitry may be further to (e.g. automatically) determine a measurement surface corresponding to the measured surface of the object by performing a statistical analysis of at least a portion of the measured surface data in respect of an interpretation direction such that a portion of the measured surface data is offset from (or beyond) the measurement surface in the interpretation direction. The processing circuitry may be further to (e.g. automatically) make a measurement relating to the object depending on the measurement surface.
Example 31: The apparatus of example 30 wherein the processing circuitry is to determine the interpretation direction depending on a surface fit to reference surface data representing at least a portion of a reference surface of the object. The processing circuitry may be to fit the said surface to the reference surface data.
Example 32: The apparatus of example 31 wherein the reference surface of the object comprises a surface of the object other than the measured surface.
Example 33: The apparatus of example 31 or 32 wherein the processing circuitry is to determine the interpretation direction depending on surfaces fit to reference surface data representing at least respective portions of a plurality of reference surfaces of the object. It may be that the respective surfaces are jointly fitted to the reference surface data representing the said plurality of reference surfaces.
Example 34: The apparatus of any one of examples 30 to 33 wherein the processing circuitry is to determine the measurement surface by performing the said statistical analysis by identifying a data point corresponding to a k^{th} percentile data point of the at least a portion of the measured surface data ordered in respect of the interpretation direction and determining the measurement surface depending on the identified data point. It may be that k is a predefined value.
Example 35: The apparatus of any one of examples 30 to 34 wherein the processing circuitry is to determine the measurement surface by performing the said statistical analysis by: orienting, or aligning and orienting, an interpretation surface with respect to the measured surface data; and providing the interpretation surface at a position along the interpretation direction depending on the statistical analysis.
Example 36: The apparatus of example 35 wherein the processing circuitry is to determine the measurement surface based on the interpretation surface.
Example 37: The apparatus of any one of examples 30 to 36 wherein the processing circuitry is to determine the measurement surface by performing the said statistical analysis by determining the measurement surface based on a statistical analysis of a restricted portion of the measured surface data corresponding to a predefined portion of the measured surface.
Example 38: The apparatus of any one of examples 30 to 37 wherein the processing circuitry is to cause any of the following based on the said measurement: adjustment of a control or calibration parameter of an additive manufacturing apparatus by which the object was manufactured; adjustment of a pre-compensation factor to be applied to the model.
Example 39: The apparatus of example 38 wherein the processing circuitry is to cause manufacture of a further object by an additive manufacturing apparatus based on the adjusted control or calibration parameter, the adjusted pre-compensation factor or the adjusted control or calibration parameter and the adjusted pre-compensation factor.
Example 40: A computer program product comprising instructions which, when the program is executed by a computer, cause the computer to carry out the method of any one of examples 1 to 25 or to perform in accordance with the processing circuitry of any one of examples 26 to 39.
Example 41: A non-transitory machine-readable storage medium having executable instructions stored thereon which, when executed (e.g. by processing circuitry), cause (e.g. the) processing circuitry to perform in accordance with the method of any one of examples 1 to 25 or to perform in accordance with the processing circuitry of the apparatus of any one of examples 26 to 39.

1. A method of making a measurement relating to an object manufactured according to a model, the object having a measured surface comprising a surface deviation relative to a corresponding surface of the model, the method comprising:
obtaining measured surface data representing at least a portion of the measured surface comprising the said surface deviation;
determining a measurement surface corresponding to the measured surface of the object by performing a statistical analysis of at least a portion of the measured surface data in respect of an interpretation direction such that a portion of the measured surface data is offset from the measurement surface in the interpretation direction; and
making a measurement relating to the object depending on the measurement surface.

2. The method of claim 1 comprising determining the interpretation direction depending on a surface fit to reference surface data representing at least a portion of a reference surface of the object.

3. The method of claim 2 wherein the reference surface of the object comprises a surface of the object other than the measured surface.

4. The method of claim 1 wherein determining the measurement surface based on the said statistical analysis comprises identifying a data point corresponding to a k^{th} percentile data point of the at least a portion of the measured surface data ordered in respect of the interpretation direction and determining the measurement surface depending on the identified data point.

5. The method of claim 1 wherein determining the measurement surface by performing the said statistical analysis comprises: orienting, or aligning and orienting, an interpretation surface with respect to the measured surface data; and providing the interpretation surface at a position along the interpretation direction depending on the statistical analysis.

6. The method of claim 1 wherein determining the measurement surface by performing the said statistical analysis comprises determining the measurement surface based on a statistical analysis of a restricted portion of the measured surface data corresponding to a predefined portion of the measured surface.

7. The method of claim 1 wherein the said surface deviation of the measured surface comprises a sink.

8. The method of claim 1 wherein the measurement surface has an orientation depending on the interpretation direction.

9. The method of claim 1 further comprising any of the following based on the said measurement: causing adjustment of a control or calibration parameter of an additive manufacturing apparatus by which the object was manufactured; causing adjustment of a pre-compensation factor to be applied to the model.

10. The method of claim 1 wherein the said portion of the measured surface data offset from the measurement surface in the interpretation direction comprises noise of the measured surface data, outlier data representing outlier portions of the measured surface data, or both noise and outlier data.

11. An apparatus comprising processing circuitry to:
obtain measured surface data representing at least a portion of a measured surface of an object, the said at least a portion of the measured surface of the object comprising a surface deformation;
determine a statistical metric based on a statistical analysis of at least a portion of the measured surface data in respect of an interpretation direction;
determine a virtual measurement surface depending on the statistical metric; and
make a measurement depending on the virtual measurement surface.

12. The apparatus of claim 11 wherein the processing circuitry is further to:
determine the interpretation direction based on a virtual surface based on reference surface data representing a reference surface of the object.

13. The apparatus of claim 12 wherein the reference surface of the object comprises a surface of the object other than the measured surface.

14. The apparatus of claim 11 wherein determining the statistical metric comprises determining a k^{th} percentile data point of the at least a portion of the measured surface data in respect of the interpretation direction.

15. A non-transitory machine-readable storage medium having executable instructions stored thereon which, when executed, cause processing circuitry to perform the method of claim 1.
